(19) United States
(12) Patent Application Publication
(10) Pub. No.: US 2023/0005899 A1
(43) Pub. Date: Jan. 5, 2023

(54) DISPLAY DEVICE

(71) Applicant: Samsung Display Co., LTD., Yongin-si (KR)

(72) Inventors: Hyun Hyang KIM, Suwon-si (KR); Da Hye KIM, Seoul (KR); Man Soo KIM, Hwaseong-si (KR); Jeong Weon SEO, Hwaseong-si (KR); Jae Sul AN, Hwaseong-si (KR); Min Gwan HYUN, Suwon-si (KR)

(73) Assignee: Samsung Display Co., LTD., Yongin-si (KR)

(21) Appl. No.: 17/835,456

(22) Filed: Jun. 8, 2022

(30) Foreign Application Priority Data
Jul. 5, 2021 (KR) 10-2021-0087680

(51) Int. Cl. H01L 25/16; H01L 33/60

(52) U.S. Cl. CPC H01L 25/167; H01L 33/60; H01L 24/24

(57) ABSTRACT

The display device comprises a first electrode and a second electrode disposed on a first surface of a substrate, the first electrode and the second electrode spaced apart from each other, least one light-emitting element disposed between the first electrode and the second electrode, a functional layer disposed on a second surface of the substrate, and a reflective layer disposed between the functional layer and the second surface of the substrate, the reflective layer overlapping the light-emitting element in a plan view.

### CROSS-REFERENCE TO RELATED APPLICATION(S)

This application claims priority to and benefits of Korean Patent Application No. 10-2021-0087680 under 35 U.S.C. § 119, filed on Jul. 5, 2021, in the Korean Intellectual Property Office, the entire contents of which are incorporated herein by reference.

### BACKGROUND

### 1. Technical Field

The disclosure relates to a display device.

### 2. Description of the Related Art

Display devices are becoming more important with developments in multimedia technology. Accordingly, various display devices such as an organic light-emitting diode (OLED) display device, a liquid crystal display (LCD) device, and the like have been used.

A display device, which is a device for displaying an image, includes a display panel such as an OLED display panel or an LCD panel. The display panel may include light-emitting elements such as light-emitting diodes (LEDs), and the LEDs may be classified into OLEDs using an organic material as a light-emitting material and inorganic LEDs (ILEDs) using an inorganic material as a light-emitting material.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments of the disclosure provide a display device which may improve emission efficiency by arranging a reflective layer between a heat dissipation layer and light-emitting elements, so that light emitted from the light-emitting elements travelling in a downward direction can be reflected.

Embodiments of the disclosure provide a display device which may improve emission efficiency and heat dissipation by selectively arranging reflective patterns only in regions where light emitted from the light-emitting elements that travels in a downward direction is incident.

However, embodiments of the disclosure are not restricted to those set forth herein. The above and other embodiments of the disclosure will become more apparent to one of ordinary skill in the art to which the disclosure pertains by referencing the detailed description of the disclosure given below.

According to an embodiment of the disclosure, a display device may include a first electrode and a second electrode disposed on a firsts surface of a substrate, the first electrode and the second electrode spaced apart from each other, at least one light-emitting element disposed between the first electrode and the second electrode, a functional layer disposed on a second surface of the substrate, and a reflective layer disposed between the functional layer and the second surface of the substrate, the reflective layer overlapping the at least one light-emitting element in a plan view.

In an embodiment, the reflective layer may include at least one optical layer. Each of the at least one optical layer includes a first inorganic film having a first refractive index, and a second inorganic film disposed on the first inorganic film and having a second refractive index. A value of the second refractive index may be different from a value of the first refractive index.

In an embodiment, the first inorganic film may include silicon nitride (SiNₓ). The second inorganic film may include silicon oxide (SiOₓ).

The reflective layer includes at least one of a reflective sheet and a reflective film, the at least one of the reflective sheet and the reflective film including a reflective material.

In an embodiment, the display device may further include a first insulating layer disposed on the first electrode and the second electrode. The first electrode and the second electrode may not overlap each other in a plan view.

In an embodiment, the at least one light-emitting element may be disposed on the first insulating layer. At least part of the at least one light-emitting element may overlap a region where the first electrode and the second electrode are spaced apart from each other and face each other in a plan view.

In an embodiment, reflective layer may overlap a region where the first electrode and the second electrode are spaced apart from each other and face each other in a plan view.

In an embodiment, the display device may include a light-blocking member, an emission area, and a light-blocking area surrounding the emission area. The light-blocking member may be disposed in the light-blocking area and may surround the emission area. The at least one light-emitting element is disposed in the emission area.

In an embodiment, the reflective layer may overlap the emission area in a plan view. A size of the reflective layer may be greater than or equal to a size of the emission area.

In an embodiment, the reflective layer may overlap the light-blocking member in a plan view.

According to an embodiment, a display device may include an emission area and a light-blocking area surrounding the emission area, a first electrode and a second electrode disposed on a first surface of a substrate in the emission area, the first electrode and the second electrode extending in a first direction and being spaced apart from each other in a second direction which intersects the first direction, light-emitting elements disposed on the first surface of the substrate, between the first electrode and the second electrode in the emission area, a light-blocking member disposed on the first surface of the substrate in the light-blocking area, the light-blocking member surrounding the emission area, a heat dissipation layer disposed on a second surface of the substrate, and a functional layer disposed between the heat dissipation layer and the substrate, the functional area overlapping the emission area in a plan view.

In an embodiment, the functional layer may include a reflective layer.

In an embodiment, the functional layer may include at least one optical layer. Each of the at least one optical layer may include a first inorganic film having a first refractive index, and a second inorganic film disposed on the first inorganic film and having a second refractive index. A value of the second refractive index may be different from a value of the first refractive index.

In an embodiment, the functional layer may not overlap at least part of the light-blocking member in a plan view.

In an embodiment, the display device may further include an adhesive layer surrounding the functional layer. The adhesive layer may overlap the light-blocking member in a plan view.

In an embodiment, end portions of each of the light-emitting elements may be disposed on the first electrode and the second electrode. At least part of each of the light-emitting elements overlaps a region where the first electrode and the second electrode are spaced apart from each other and face each other in a plan view.

In an embodiment, the functional layer may include a passivation layer, and a reflective coating layer disposed on a surface of the passivation layer, and the surface of the passivation layer faces the second surface of the substrate.

According to an embodiment, a display device may include emission areas and light-blocking areas surrounding the emission areas, arrays of light-emitting elements disposed on a first surface of a substrate, in the emission areas, and reflective patterns disposed on a second surface of the substrate. The reflective patterns may be disposed to be spaced apart from each other.

In an embodiment, the reflective patterns may be disposed in the emission areas.

In an embodiment, the display device may further include a light-blocking member disposed on the first surface of the substrate, in the light-blocking areas. The light-blocking member may surround the emission areas. The reflective patterns may not overlap at least part of the light-blocking member in a plan view.

According to the aforementioned and other embodiments of the disclosure, as a reflective layer is disposed between a heat dissipation layer and light-emitting elements, light emitted from the light-emitting elements travelling in a downward direction can be reflected in the display direction of a display device, and as a result, the emission efficiency of the display device may be improved.

Also, as reflective patterns are selectively disposed in a region where the light emitted from the light-emitting elements travelling in the downward direction is mainly incident, the emission efficiency and the heat dissipation characteristics of the display device can be improved.

Other features and embodiments may be apparent from the following detailed description, the drawings, and the claims.

### BRIEF DESCRIPTION OF THE DRAWINGS

The above and other embodiments and features of the disclosure will become more apparent by describing in detail embodiments thereof with reference to the attached drawings, in which:

FIG. 1 is a schematic plan view of a display device according to an embodiment of the disclosure;

FIG. 2 is a schematic cross-sectional view of the display device of FIG. 1;

FIG. 3 is a schematic layout view of a light-emitting element layer of a display panel according to an embodiment of the disclosure;

FIG. 4 is a schematic cross-sectional view of a first subpixel according to an embodiment of the disclosure;

FIG. 5 is a schematic perspective view of a light-emitting element according to an embodiment of the disclosure;

FIG. 6 is an enlarged schematic cross-sectional view of an area Q of FIG. 4;

FIG. 7 is an enlarged schematic cross-sectional view of the area Q of FIG. 4;

FIG. 8 is a schematic cross-sectional view of a display device according to an embodiment of the disclosure;

FIG. 9 is a schematic layout view illustrating the arrangement of a light-blocking member and a second functional layer of the display device of FIG. 8 relative to each other;

FIG. 10 is a schematic cross-sectional view illustrating how light emitted from light-emitting elements of the display device of FIG. 8 travels in a downward direction;

FIG. 11 is a schematic cross-sectional view of a second functional layer according to an embodiment of the disclosure;

FIG. 12 is a schematic cross-sectional view of a display device according to an embodiment of the disclosure;

FIG. 13 is a schematic cross-sectional view of a display device according to an embodiment of the disclosure;

FIG. 14 is a schematic cross-sectional view of a display device according to an embodiment of the disclosure;

FIG. 15 is a schematic cross-sectional view of a display device according to an embodiment of the disclosure;

FIG. 16 is a schematic layout view illustrating the arrangement of a light-blocking member and a second functional layer of the display device of FIG. 15 relative to each other;

FIG. 17 is a schematic cross-sectional view illustrating how light emitted from light-emitting elements of the display device of FIG. 15 travels in a downward direction;

FIG. 18 is a schematic cross-sectional view of a display device according to an embodiment of the disclosure;

FIG. 19 is a schematic perspective view of a display device being rolled;

FIG. 20 is a schematic cross-sectional view of the display device of FIG. 19; and

FIG. 21 is a schematic cross-sectional view of the display device of FIG. 20 being rolled in a downward direction.

### DETAILED DESCRIPTION OF THE EMBODIMENTS

The disclosure will now be described more fully hereinafter with reference to the accompanying drawings in which the embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

“About,” “substantially,” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Hereinafter, embodiments will be described with reference to the accompanying drawings.

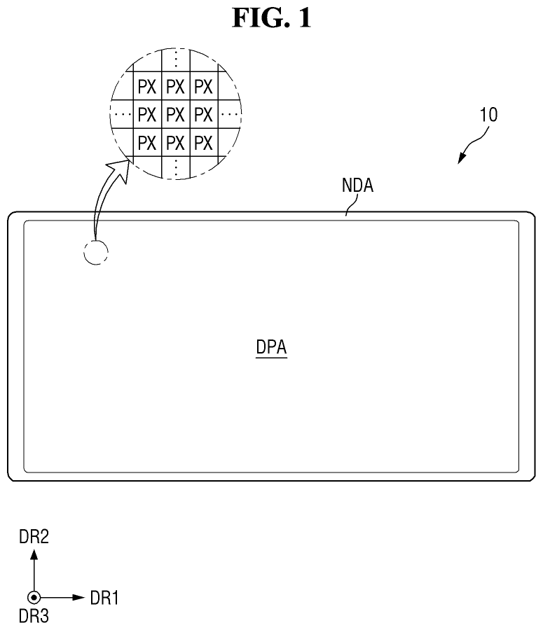

FIG. 1 is a schematic plan view of a display device according to an embodiment of the disclosure.

Referring to FIG. 1, a display device 10 displays a moving or still image. The display device 10 may refer to electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display, a mobile communication terminal, an electronic notepad, an electronic book, a portable multimedia player (PMP), a navigation device, a gaming console, a digital camera, and a camcorder.

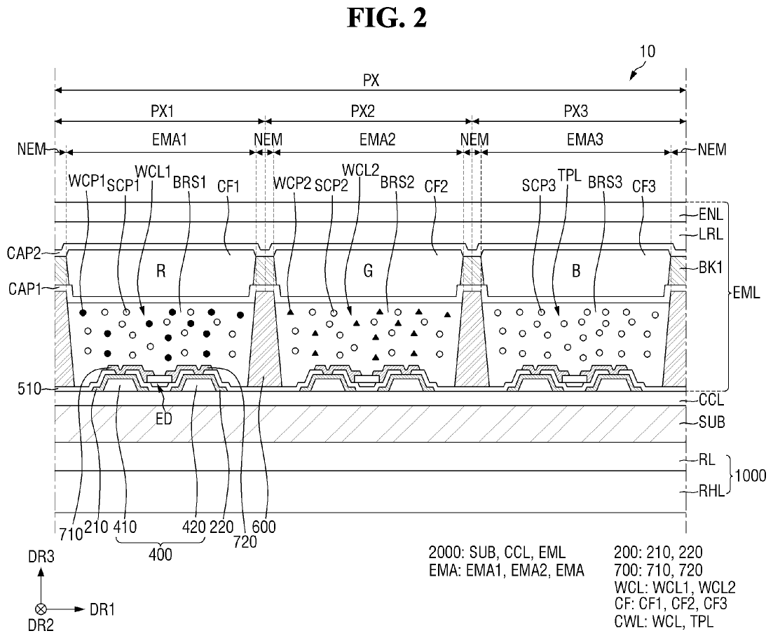

The display device 10 may include a display panel (2000 of FIG. 2) that provides a display screen. Examples of the display panel 2000 include an inorganic light-emitting diode (ILED) display panel, an organic LED (OLED) display panel, a quantum-dot light-emitting diode (QLED) display panel, a plasma display panel (PDP), and a field emission display (FED) panel. The display panel 2000 of the display device 10 will hereinafter be described as being an ILED display panel, but the disclosure is not limited thereto.

First, second, and third directions DR1, DR2, and DR3 are defined as illustrated in the accompanying drawings. The first and second directions DR1 and DR2 may be directions that are perpendicular to each other within the same plane. The third direction DR3 may be a direction that is perpendicular to the plane that includes the first and second directions DR1 and DR2. The third direction DR3 may be perpendicular to each of the first and second directions DR1 and DR2. The third direction DR3 refers to the thickness direction of the display device 10.

The display device 10 may have a rectangular shape that is longer in the first direction DR1 than in the second direction DR2 in a plan view. The corners at which the long sides and the short sides of the display device 10 meet may be right-angled, but the disclosure is not limited thereto. In other examples, the corners at which the long sides and the short sides of the display device 10 meet may be rounded. The planar shape of the display device 10 is not particularly limited and may vary. The display device 10 may have a rectangular shape, such as a square shape, a rectangular shape with rounded corners, a non-tetragonal polygonal shape, or a circular shape.

The display surface of the display device 10 may be disposed on a side, in the third direction DR3 (or the thickness direction), of the display device 10. Unless specified otherwise, the terms “above” and “top,” as used herein, refer to the third direction DR3 (or the display direction of the display device 10), and the term “top surface,” as used herein, refers to a surface that is directed to the third direction DR3. Also, unless specified otherwise, the terms “below” and “bottom,” as used herein, refer to the opposite direction of the third direction DR3 (or the opposite direction of the display direction of the display device 10), and the term “bottom surface”, as used herein, refers to a surface that is directed to the opposite direction of the third direction DR3. Also, unless specified otherwise, the terms “left,” “right,” “upper,” and “lower,” as used herein, refer to their respective directions as viewed from above the display device 10. For example, the term “right” refers to the first direction DR1, the term “left” refers to the opposite direction of the first direction DR1, the term “upper” refers to the second direction DR2, and the term “lower” refers to the opposite direction of the second direction DR2.

The display device 10 may include a display area DPA and a non-display area NDA. The display area DPA is an area in which a screen is displayed, and the non-display area NDA is an area in which a screen is not displayed.

The shape of the display area DPA may conform to the shape of the display device 10. For example, the display area DPA may have a similar shape to the display device 10, i.e., a rectangular shape, in a plan view. The display area DPA may account for the middle part of the display device 10.

The display area DPA may include pixels PX. The pixels PX may be arranged in row and column directions. The pixels PX may have a rectangular or square shape in a plan view, but the disclosure is not limited thereto. In other examples, the pixels PX may have a rhombus shape having sides inclined with respect to a direction. The pixels PX may be alternately arranged in a stripe or PENTILE™ fashion.

The non-display area NDA may be disposed around the display area DPA. The non-display area NDA may surround the entire display area DPA or part of the display area DPA. The display area DPA may have a rectangular shape, and the non-display area NDA may be disposed adjacent to the four sides of the display area DPA. The non-display area NDA may form the bezel of the display device 10. In the non-display area NDA, lines, circuit drivers, or pad units, in which external devices are mounted, may be disposed.

FIG. 2 is a schematic cross-sectional view of the display device of FIG. 1.

Referring to FIG. 2, the display area DPA of the display device 10 includes pixels PX, which are arranged in multiple rows and multiple columns. The pixels PX refer to minimal units that are repeated one after another for displaying an image.

Each of the pixels PX may include subpixels PXn (where n is a natural number from 1 to 3), which emit light of different colors, to display a full color. For example, each of the pixels PX may include a first subpixel PX1, which emits light of a first color, a second subpixel PX2, which emits light of a second color, and a third subpixel PX3, which emits light of a third color. For example, the first, second, and third colors may be red, green, and blue, respectively. FIG. 2 illustrates that each of the pixels PX includes three subpixels PXn, but the disclosure is not limited thereto. In other examples, each of the pixels PX may include more than three subpixels PXn.

Each of the subpixels PXn may include an emission area EMA and a light-blocking area NEM around the emission area EMA. The first subpixel PX1 may include a first emission area EMA1, the second subpixel PX2 may include a second emission area EMA2, and the third subpixel PX3 may include a third emission area EMA3.

The first, second, and third emission areas EMA1, EMA2, and EMA3 may be areas that light emitted from a display area EML of the display panel 2000 is provided to the outside, and light-blocking areas NEM may be areas that do not transmit the light emitted from the display layer EML therethrough. The first emission area EMA1 may emit light of the first color, the second emission area EMA2 may emit light of the second color, and the third emission area EMA3 may emit light of the third color. For example, the first, second, and third colors may be red, green, and blue, respectively.

The light-blocking areas NEM may be disposed to surround the first, second, and third emission areas EMA1, EMA2, and EMA3 in a plan view. The first, second, and third emission areas EMA1, EMA2, and EMA3 may be defined, or surrounded in a plan view, by the light-blocking areas NEM.

The display device 10 may include the display panel 2000 and a functional layer 1000, which is disposed on the bottom surface of the display panel 2000.

The display panel 2000 may include a substrate SUB, a circuit element layer CCL, which is disposed on the substrate SUB, and the display layer EML, which is disposed on the circuit element layer CCL.

The substrate SUB may be a base substrate or a base member and may include an insulating material such as a polymer resin. The substrate SUB may include an insulating material such as glass, quartz, or a polymer resin. The substrate SUB may be a rigid substrate or may be a flexible substrate that is bendable, foldable, or rollable.

The circuit element layer CCL may be disposed on the substrate SUB. The circuit element layer CCL may be disposed on a first surface of the substrate SUB and may drive the pixels PX. The circuit element layer CCL may include one or more transistors to drive the display layer EML.

The display layer EML may be disposed on the substrate SUB and the circuit element layer CCL. The display layer EML may include a light-emitting element layer, which includes an electrode layer 200, arrays of light-emitting elements ED, and contact electrodes 700, a color control structure, which includes a wavelength conversion layer WCL, a light-transmitting pattern TPL, and color filters CF, a first light-blocking member BK1, and an encapsulation layer ENL.

The light-emitting element layer may be disposed on one surface of the circuit element layer CCL. The light-emitting element layer may include a first electrode, an emission layer, and a second electrode of each of the pixels PX. The emission layer may include ILEDs, but the disclosure is not limited thereto. In other examples, the emission layer may include OLEDs.

The light-emitting element layer may include a first bank 400, a second bank 600, the electrode layer 200, the contact electrodes 700, the arrays of light-emitting elements ED, and a first insulating layer 510.

The first bank 400 may be disposed on the circuit element layer CCL. The first bank 400 may be disposed in the first, second, and third emission areas EMA1, EMA2, and EMA3, which are the emission areas of the first, second, and third subpixels PX1, PX2, and PX3. The first bank 400 may include sub-banks, and sub-banks may be disposed to be spaced apart from each other. For example, the first bank 400 may include first sub-banks 410 and second sub-banks 420, which are spaced apart from each other.

The electrode layer 200 may be disposed on the first bank 400. The electrode layer 200 may include first electrodes 210 and second electrodes 220, which are spaced apart from the first electrodes 210. The first electrodes 210 may be disposed on the first sub-banks 410, and the second electrodes 220 may be disposed on the second sub-banks 420.

The first insulating layer 510 may be disposed on the first electrodes 210 and the second electrodes 220. The first insulating layer 510 may be disposed on the first electrodes 210 and the second electrodes 220 to expose at least parts of the first electrodes 210 and the second electrodes 220.

The second bank 600 may be disposed on the first insulating layer 510. The second bank 600 may be disposed in the light-blocking areas NEM along the boundaries of each of the first, second, and third subpixels PX1, PX2, and PX3. The second bank 600 may include openings, which expose the first bank 400 and the arrays of light-emitting elements ED in the first, second, and third emission areas EMA1, EMA2, and EMA3. The openings of the second bank 600 may also expose the first electrodes 210 and the second electrodes 220 in the first, second, and third emission areas EMA1, EMA2, and EMA3.

During the fabrication of the display device 10, the second bank 600 may function as a barrier that allows ink containing light-emitting elements ED dispersed therein to be properly sprayed into the emission area EMA of each subpixel PXn, without overflowing into the emission areas EMA of other neighboring subpixels PXn. An inkjet printing process may be used to provide and align the light-emitting elements ED during the fabrication of the display device 10. Also, the second bank 600 may function as a barrier for forming the wavelength conversion layer WCL and the light-transmitting pattern TPL in the emission area EMA. The wavelength conversion layer WCL and the light-transmitting pattern TPL may be disposed in areas defined by (surrounded by) the second bank 600.

The second bank 600 may prevent light emitted from the light-emitting elements ED of each subpixel PXn from being mixed into the emission areas EMA of other neighboring subpixels PXn. The second bank 600 may include an organic material. The second bank 600 may include a light-absorbing material capable of absorbing visible light. For example, the second bank 600 may include black matrix a material. The second bank 600 may be a type of light-blocking member. However, the disclosure is not limited to this. In other embodiments, the second bank 600 may include a barrier including an organic material and a reflective layer disposed on the outer surfaces of the barrier.

Arrays of light-emitting elements ED may be disposed on the first insulating layer 510, between the first sub-banks 410 and the second sub-banks 420. In each of the subpixels PXn, light-emitting elements ED may be disposed on the first insulating layer 510, between the first and second electrodes 210 and 220, such that both end portions thereof may be placed on the first and second electrodes 210 and 220.

Light-emitting elements ED may be disposed in each of the first, second, and third emission areas EMA1, EMA2, and EMA3 of the first, second, and third subpixels PX1, PX2, and PX3. The light-emitting elements ED may be provided in each of the first, second, and third subpixels PX1, PX2, and PX3. In each of the first, second, and third subpixels PX1, PX2, and PX3, the light-emitting elements ED may be disposed between the first and second electrodes 210 and 220, exposed by the openings of the second bank 600. Thus, in each of the first, second, and third subpixels PX1, PX2, and PX3, at least parts of the light-emitting elements ED may be exposed in a downward direction in the gap between the first and second electrodes 210 and 220.

The light-emitting elements ED may emit light of a particular wavelength range. For example, the light-emitting elements ED may emit light of the third color (or blue light) having a peak wavelength of 480 nm or less, preferably, a peak wavelength of 445 nm to 480 nm. However, the disclosure is not limited to this example. In another example, the light-emitting elements ED may emit green light or red light.

The contact electrodes 700 may be disposed on the arrays of light-emitting elements ED. The contact electrodes 700 may be in contact with the first electrodes 210 and the second electrodes 220, exposed by the first insulating layer 510, and with the arrays of light-emitting elements ED. The contact electrodes 700 may electrically connect the first electrodes 210, the second electrodes 220, and the light-emitting elements ED by being in contact with the first electrodes 210, the second electrodes 220, and the arrays of light-emitting elements ED.

The contact electrodes 700 may include first contact electrodes 710 and second contact electrodes 720, which are spaced apart from the first contact electrodes 710. The first contact electrodes 710 and the second contact electrodes 720 may be electrically insulated from one another.

The first contact electrodes 710 may be disposed on the first electrodes 210, and the second contact electrodes 720 may be disposed on the second electrodes 220. The first contact electrodes 710 may electrically connect the first electrodes 210 and the first end portions of the arrays of light-emitting elements ED. The first contact electrodes 710 may electrically contact the first electrodes 210 and the first end portions of the arrays of light-emitting elements ED, exposed by the first insulating layer 510. The second contact electrodes 720 may electrically connect the second electrodes 220 and the second end portions of the arrays of light-emitting elements ED. The second contact electrodes 720 may electrically contact the second electrodes 220 and the second end portions of the arrays of light-emitting elements ED, exposed by the first insulating layer 510. The first end portions of the light-emitting elements ED may be electrically connected to the first electrodes 210 through the first contact electrodes 710, and the second end portions of the light-emitting elements ED may be electrically connected to the second electrodes 220 through the second contact electrodes 720.

The wavelength conversion layer WCL and the light-transmitting pattern TPL may be disposed on the contact electrodes 700. The wavelength conversion layer WCL and the light-transmitting pattern TPL may be disposed in the openings of the second bank 600. The wavelength conversion layer WCL and the light-transmitting pattern TPL may be disposed on the contact electrodes 700, in the openings of the second bank 600, to cover the members disposed therebelow.

The wavelength conversion layer WCL and the light-transmitting pattern TPL may be disposed on the arrays of light-emitting elements ED. The wavelength conversion layer WCL and the light-transmitting pattern TPL may overlap with the wavelength conversion layer WCL and the light-transmitting pattern TPL in the third direction DR3. The wavelength conversion layer WCL and the light-transmitting pattern TPL may transmit light from the arrays of light-emitting elements ED, after converting (or maintaining) the wavelength of the incident light.

The wavelength conversion layer WCL and the light-transmitting pattern TPL may be disposed separately on the first, second, and third subpixels PX1, PX2, and PX3. The wavelength conversion layer WCL and the light-transmitting pattern TPL may be disposed in the emission areas of the first, second, and third subpixels PX1, PX2, and PX3, i.e., in the first, second, and third emission areas EMA1, EMA2, and EMA3, and may be isolated from one another by the second bank 600, which is disposed in the light-blocking areas NEM.

The wavelength conversion layer WCL may be disposed in subpixels where the wavelength of light emitted from the light-emitting element layer needs to be converted because the emitted light may have a different color from the color of the corresponding subpixels. The light-transmitting pattern TPL may be disposed in a subpixel where the light emitted from the light-emitting element layer has the same color as the corresponding subpixel. For example, the wavelength conversion layer WCL may be disposed in the first and second subpixels PX1 and PX2, and the light-transmitting pattern TPL may be disposed in the third subpixel PX3.

The wavelength conversion layer WCL may include first and second wavelength conversion patterns WCL1 and WCL2, which are disposed in the first and second subpixels PX1 and PX2, respectively.

The first wavelength conversion pattern WCL1 may be disposed in the first emission area EMA1 of the first subpixel PX1, defined by (surrounded by) the second bank 600, in a plan view. The first wavelength conversion pattern WCL1 may convert light emitted from the light-emitting elements ED of the first subpixel PX1 into first-color light and may emit the first-color light. The first wavelength conversion pattern WCL1 may convert the light emitted from the light-emitting elements ED of the first subpixel PX1 into red light and may emit the red light.

The first wavelength conversion pattern WCL1 may include a first base resin BRS1 and a first wavelength conversion material WCP1, which is dispersed in the first base resin BRS1. The first wavelength conversion pattern WCL1 may further include a first scatterer SCP1, which is dispersed in the first base resin BRS1.

The second wavelength conversion pattern WCL2 may be disposed in the second emission area EMA2 of the second subpixel PX2, defined (surrounded) by the second bank 600, in a plan view. The second wavelength conversion pattern WCL2 may convert light emitted from the light-emitting elements ED of the second subpixel PX2 into second-color light and may emit the second-color light. The second wavelength conversion pattern WCL2 may convert the light emitted from the light-emitting elements ED of the second subpixel PX2 into green light and may emit the green light.

The second wavelength conversion pattern WCL2 may include a second base resin BRS2 and a second wavelength conversion material WCP2, which is dispersed in the second base resin BRS2. The second wavelength conversion pattern WCL2 may further include a second scatterer SCP2, which is dispersed in the second base resin BRS2.

The light-transmitting pattern TPL may be disposed in the third emission area EMA of the third subpixel PX3. The emission area EMA may be surrounded by the second bank 600 in a plan view. The light-transmitting pattern TPL may emit light emitted from the light-emitting elements ED of the third subpixel PX3, while maintaining the wavelength of the incident light. The light-transmitting pattern TPL may emit the light emitted from the light-emitting elements ED of the third subpixel PX3, for example, blue light, while maintaining the wavelength of the blue light.

The light-transmitting pattern TPL may include a third base resin BRS3. The light-transmitting pattern TPL may further include a third scatterer SCP3, which is dispersed in the third base resin BRS3.

The first, second, and third base resins BRS1, BRS2, and BRS3 may include a transparent organic material. For example, the first, second, and third base resins BRS1, BRS2, and BRS3 may include an epoxy resin, an acrylic resin, a cardo resin, or an imide resin. The first, second, and third base resins BRS1, BRS2, and BRS3 may all include a same material, but the disclosure is not limited thereto.

The first, second, and third scatterers SCP1, SCP2, and SCP3 may have a different refractive index from the first, second, and third base resins BRS1, BRS2, and BRS3. The first, second, and third scatterers SCP1, SCP2, and SCP3 may include particles of a metal oxide or particles of an organic material. Here, the metal oxide may be titanium oxide (TiO₂), zirconium oxide (ZrO₂), aluminum oxide (Al₂O₃), indium oxide (In₂O₃), zinc oxide (ZnO), or tin oxide (SnO₂), and the organic material may be an acrylic resin or a urethane resin. The first, second, and third scatterers SCP1, SCP2, and SCP3 may include a same material.

The first wavelength conversion material WCP1 may convert third-color light or second-color light into first-color light, and the second wavelength conversion material WCP2 may convert third-color light into second-color light. For example, the first wavelength conversion material WCP1 may be a material converting blue light into red light or green light into red light, and the second wavelength conversion material WCP2 may be a material converting blue light into green light. The first and second wavelength conversion materials WCP1 and WCP2 may be quantum dots (QDs), quantum rods, fluorescent materials, or phosphorescent materials. The QDs may include group IV nanocrystals, group II-VI compound nanocrystals, group III-V compound nanocrystals, group IV-VI nanocrystals, or a combination thereof.

Each of the QDs may include a core and a shell overcoating the core. For example, the core may include at least one of CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, and Ge, but the disclosure is not limited thereto. The shell may include at least one of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, and PbTe, but the disclosure is not limited thereto.

The fluorescent materials may be inorganic fluorescent materials, and inorganic fluorescent substances such as garnets, silicates, sulfides, oxynitrides, nitrides, or aluminates may be used as the fluorescent materials. For example, the inorganic fluorescent substances may include at least one of Y₃Al₅O₁₂:Ce³⁺(YAG:Ce), Tb₃Al₅O₁₂:Ce³⁺(TAG:Ce), (Sr, Ba, Ca)₂SiO₄:Eu²⁺, (Sr, Ba, Ca, Mg, Zn)₂Si(OD)₄:Eu²⁺D=F, Cl, S, N, Br, Ba₂MgSi₂O₇:Eu²⁺, Ba₂SiO₄:Eu²⁺, Ca₃(Sc, Mg)₂Si₃O₁₂:Ce³⁺, (Ca, Sr)S:Eu²⁺, (Sr, Ca)Ga₂S₄:Eu²⁺, SrSi₂O₂N₂:Eu²⁺, SiAlON:Ce³⁺, β-SiAlON:Eu²⁺, Ca-α-SiAlON:Eu²⁺, Ba₃Si₆O₁₂N₂:Eu²⁺, CaAlSiN₃:Eu²⁺, (Sr, Ca)AlSiN₃:Eu²⁺, Sr₂Si₅N₈:Eu²⁺, (Sr, Ba)Al₂O₄:Eu²⁺, (Mg, Sr)Al₂O₄:Eu²⁺, and BaMg₂Al₁₆O₂₇:Eu²⁺. However, the disclosure is not limited to this, and the fluorescent materials may include organic fluorescent materials.

The display layer EML may further include a first capping layer CAP1. The first capping layer CAP1 may be disposed on the wavelength conversion layer WCL, the light-transmitting pattern TPL, and the second bank 600 to cover the wavelength conversion layer WCL, the light-transmitting pattern TPL, and the second bank 600. For example, the first capping layer CAP1 may seal the first wavelength conversion pattern WCL1, the second wavelength conversion pattern WCL2, the light-transmitting pattern TPL, and the second bank 600 and may thereby prevent the first wavelength conversion pattern WCL1, the second wavelength conversion pattern WCL2, the light-transmitting pattern TPL from being damaged or contaminated.

The first capping layer CAP1 may include an inorganic material. For example, the first capping layer CAP1 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. FIG. 2 illustrates that the first capping layer CAP1 consists of a single layer, but the disclosure is not limited thereto. In other examples, the first capping layer CAP1 may be formed as a multilayer in which inorganic layers of the aforementioned materials for forming the first capping layer CAP1 are alternately stacked.

The first light-blocking member BK1 may be disposed on the first capping layer CAP1. The first light-blocking member BK1 may be disposed on the first capping layer CAP1, in each of the light-blocking areas NEM, along the boundaries of each of the first, second, and third subpixels PX1, PX2, and PX3. The first light-blocking member BK1 may overlap with the second bank 600 in the thickness direction of the display device 10 (e.g., in the third direction DR3, or in a plan view).

The first light-blocking member BK1 not only blocks the emission of light, but also suppresses the reflection of external light. The first light-blocking member BK1 may be formed as a lattice surrounding the first, second, and third emission areas EMA1, EMA2, and EMA3, in a plan view.

The first light-blocking member BK1 may include an organic material. For example, the first light-blocking member BK1 may include a light-absorbing material capable of absorbing light of a visible wavelength range. As the first light-blocking member BK1 includes a light-absorbing material and is disposed along the boundaries of each of the first, second, and third subpixels PX1, PX2, and PX3, the first light-blocking member BK1 may define the first, second, and third emission areas EMA1, EMA2, and EMA3. The first light-blocking member BK1 may surround the first, second, and third emission areas EMA1, EMA2, and EMA3.

The color filters CF may be disposed on the first capping layer CAP1, in the display area DPA. The color filters CF may be disposed in spaces defined (surrounded) by the first light-blocking member BK1. The color filters CF may be disposed in the emission areas EMA of the subpixels PXn.

The color filters CF may include first, second, and third color filters CF1, CF2, and CF3.

The first color filter CF1 may be disposed in the first emission area EMA1 of the first subpixel PX1, the second color filter CF2 may be disposed in the second emission area EMA2 of the second subpixel PX2, and the third color filter CF3 may be disposed in the third emission area EMA3 of the third subpixel PX3. The first, second, and third color filters CF1, CF2, and CF3 may be surrounded by the first light-blocking member BK1.

The first, second, and third color filters CF1, CF2, and CF3 may include a colorant such as a dye or a pigment capable of absorbing wavelengths other than a selected wavelength. The first color filter CF1 may selectively transmit first-color light (e.g., red light) and block or absorb second-color light (e.g., green light) and third-color light (e.g., blue light). The second color filter CF2 may selectively transmit second-color light (e.g., green light) and block or absorb first-color light (e.g., red light) and third-color light (e.g., blue light). The third color filter CF3 may selectively transmit third-color light (e.g., blue light) therethrough and block or absorb first-color light (e.g., red light) and second-color light (e.g., green light. For example, the first color filter CF1 may be a red color filter, the second color filter CF2 may be a green color filter, and the third color filter CF3 may be a blue color filter.

The first, second, and third color filters CF1, CF2, and CF3 may reduce the reflection of external light by absorbing light introduced from the outside of the display device 10. Thus, the first, second, and third color filters CF1, CF2, and CF3 may prevent any color distortion that may be caused by the reflection of external light.

As the color filters CF are disposed on the first and second wavelength conversion patterns WCL1 and WCL2 and the light-transmitting pattern TPL, the display device 10 may not need a separate substrate for the color filters CF. Thus, the thickness of the display device 10 can be reduced.

A second capping layer CAP2 may be disposed on the color filters CF. The second capping layer CAP2 may be disposed on the first, second, and third color filters CF1, CF2, and CF3 and the first light-blocking member BK1 to cover the first, second, and third color filters CF1, CF2, and CF3 and the first light-blocking member BK1. The second capping layer CAP2 may protect the color filters CF.

A passivation layer LRL may be disposed on the second capping layer CAP2. The passivation layer LRL may be disposed on the color filters CF and the first light-blocking member BK1 to prevent oxygen or moisture from infiltrating into the wavelength conversion layer WCL, the light-transmitting pattern TPL, and the color filters CF. To this end, the passivation layer LRL may include at least one inorganic film. The passivation layer LRL may be disposed to cover the wavelength conversion layer WCL, the light-transmitting pattern TPL, the color filters CF, and the first light-blocking member BK1.

The encapsulation layer ENL may be disposed on the passivation layer LRL. The encapsulation layer ENL may be disposed to seal the top surface and the sides of the display layer EML. For example, the encapsulation layer ENL may include at least one inorganic film and may prevent the infiltration of oxygen or moisture. Also, the encapsulation layer ENL may include at least one organic film and may protect the display panel 2000 from foreign material such as dust.

The functional layer 1000 may be disposed below the display panel 2000. For example, the functional layer 1000 may be disposed on a second surface of the substrate SUB of the display panel 2000. The second surface of the substrate SUB where the functional layer 1000 is disposed may be the bottom surface of the substrate SUB.

The functional layer 1000 may include multiple layers. For example, the functional layer 1000 may include a first functional layer RHL and a second functional layer RL. The first functional layer RHL may be a heat dissipation layer RHL, and the second functional layer RL may be a reflective layer RL.

The first functional layer and the heat dissipation layer may both be referred to by “RHL,” and the second functional layer and the reflective layer may both be referred to by “RL.”

The first functional layer RHL may be disposed on the second surface of the substrate SUB. The first functional layer RHL may be disposed below the substrate SUB and may release heat generated by the display panel 2000. The first functional layer RHL may include a material that conducts heat and may thus dissipate heat dissipation property. For example, the first functional layer RHL may include a single graphite layer or a stack including a graphite layer.

The second functional layer RL may be disposed between the substrate SUB and the first functional layer RHL. The second functional layer RL may be disposed on the bottom surface of the substrate SUB, and the first functional layer RHL may be disposed on the bottom surface of the second functional layer RL. As will be described later, the second functional layer RL may reflect downward travelling light emitted from the arrays of light-emitting elements ED included in the display layer EML of the display panel 2000 and may thus allow the light to travel in the display direction. The second functional layer RL will be described later in further detail.

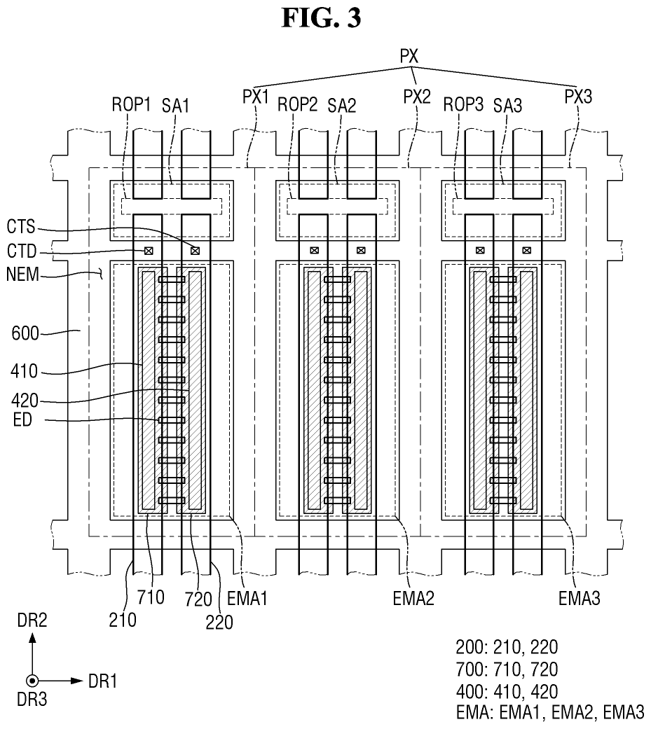

FIG. 3 is a schematic layout view of a light-emitting element layer of a display panel according to an embodiment of the disclosure.

Referring to FIG. 3, the light-emitting element layer may have the same structure in first, second, and third subpixels PX1, PX2, and PX3. Thus, descriptions of the structures of the light-emitting element layer in the second and third subpixels PX2 and PX3 may be substantially similar to the description of the structure of the light-emitting element layer in the first subpixel PX1.

The first subpixel PX1 may include a first emission area EMA1 and a light-blocking area NEM, the second subpixel PX2 may include a second emission area EMA2 and a light-blocking area NEM, and the third subpixel PX3 may include a third emission area EMA3 and a light-blocking area NEM. The first, second, and third emission areas EMA1, EMA2, and EMA3 may be defined as areas that output light emitted from arrays of light-emitting elements ED. The light-blocking areas NEM may be defined as areas that do not output light because the light emitted from the arrays of light-emitting elements ED do not reach those areas. The first, second, and third emission areas EMA1, EMA2, and EMA3 may be spaced apart from one another.

Each of the first, second, and third emission areas EMA1, EMA2, and EMA3 may include a region where light-emitting elements ED are disposed and the surroundings of the region where the light-emitting elements ED are disposed. Each of the first, second, and third emission areas EMA1, EMA2, and EMA3 may also include regions that outputs light that is emitted from the light-emitting elements ED and then reflected or refracted by other components.

Each subpixel PXn may include a subarea SAn (where n is a natural number from 1 to 3), which is disposed in the light-blocking area NEM of each subpixel PXn. The first subpixel PX1 may include a first subarea SA1, which is disposed in the light-blocking area NEM of the first subpixel PX1, the second subpixel PX2 may include a second subarea SA2, which is disposed in the light-blocking area NEM of the second subpixel PX2, and the third subpixel PX3 may include a third subarea SA3, which is disposed in the light-blocking area NEM of the third subpixel PX3.

The light-emitting elements ED may not be disposed in the subarea SAn of each subpixel PXn. In each subpixel PXn, the subarea SAn may be disposed on the upper side (or a first side in the second direction DR2) of an emission area EMAn. For example, the first subarea SA1 may be disposed on the upper side of the first emission area EMA1 of the first subpixel PX1, the second subarea SA2 may be disposed on the upper side of the second emission area EMA2 of the second subpixel PX2, and the third subarea SA3 may be disposed on the upper side of the third emission area EMA3 of the third subpixel PX3. Each subarea SAn may be disposed between the emission areas EMAn of a pair of adjacent subpixels PXn in the second direction DR2.

Each subarea SAn may include a separation part ROPn. For example, the first subarea SA1 may include a first separation part ROP1, the second subarea SA2 may include a second separation part ROP2, and the third subarea SA3 may include a third separation part ROP3. The separation part ROPn of each subarea SAn may be a region where first and second electrodes 210 and 220 included in the electrode layer 200 are divided.

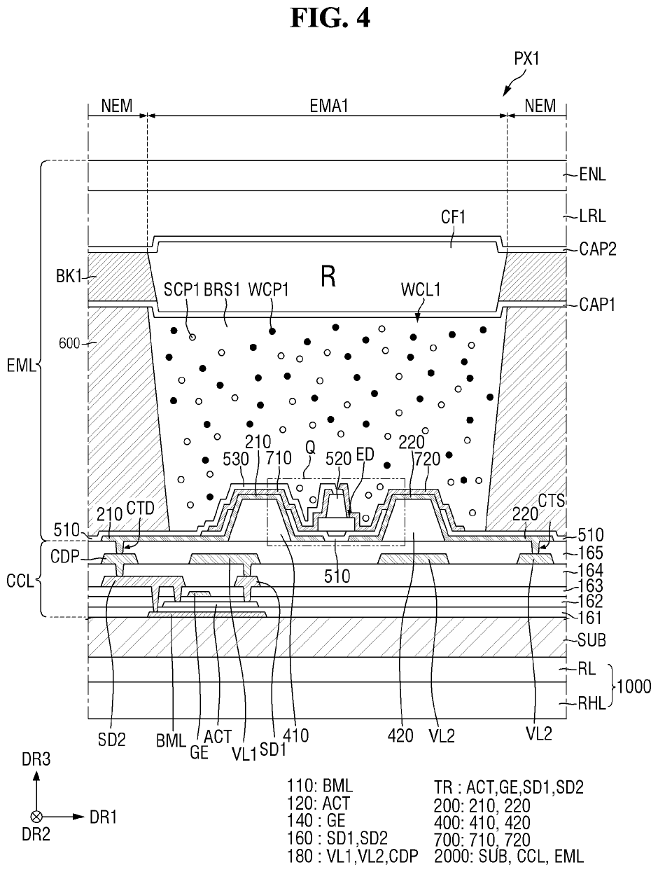

FIG. 4 is a schematic cross-sectional view of a first subpixel according to an embodiment of the disclosure.

The structure of the circuit element layer CCL, which is disposed on the substrate SUB, will hereinafter be described with reference to FIG. 4. FIG. 4 illustrates a schematic cross-sectional structure of a first subpixel PX1.

Referring to FIG. 4, the circuit element layer CCL may include a lower metal layer 110, a buffer layer 161, first, second, and third conductive layers 140, 160, and 180, a semiconductor layer 120, a gate insulating film 162, an interlayer insulating film 163, a passivation layer 164, and a via layer 165.

The lower metal layer 110 may be disposed on the substrate SUB. The lower metal layer 110 may include a metal pattern BML. The metal pattern BML, may be a light-blocking layer capable of protecting an active material layer ACT of a transistor TR from external light. The lower metal layer 110 may include a material capable of blocking light. For example, the lower metal layer 110 may include an opaque metal material capable of blocking the transmission of light.

The metal pattern BML may be disposed to cover at least the entire channel region of the active material layer ACT of the transistor TR, but the disclosure is not limited thereto. In other examples, the metal pattern BML may not be provided.

The buffer layer 161 may be disposed on the lower metal layer 110. The buffer layer 161 may be disposed to cover the entire surface of the substrate SUB where the lower metal layer 110 is disposed. The substrate SUB may be susceptible to moisture, and buffer layer 161 may protect the transistor TR from moisture that may penetrate through the substrate SUB. The buffer layer 161 may consist of inorganic layers that are alternately stacked. For example, the buffer layer 161 may be formed of multiple layers in which inorganic layers of at least one of silicon oxide (SiOₓ), silicon nitride (SiNₓ), and silicon oxynitride (SiOₓN_{y}) are alternately stacked.

The semiconductor layer 120 may be disposed on the buffer layer 161. The semiconductor layer 120 may include the active material layer ACT of the transistor TR. The active material layer ACT may overlap the metal pattern BML of the lower metal layer 110.

FIG. 4 illustrates only one transistor TR included in the first subpixel PX1 of the display device 10, but the disclosure is not limited thereto. The first subpixel PX1 of the display device 10 may include more than one transistor. For example, the first subpixel PX1 of the display device 10 may include two or three transistors.

The semiconductor layer 120 may include polycrystalline silicon, monocrystalline silicon, or an oxide semiconductor. For example, in case that the semiconductor layer 120 includes polycrystalline silicon, which is formed by crystallizing amorphous silicon, the active material layer ACT may include multiple regions doped with impurities and a channel region between the doped regions. In another example, the semiconductor layer 120 may include an oxide semiconductor. The oxide semiconductor may be, for example, indium tin oxide (ITO), indium zinc oxide (IZO), indium gallium oxide (IGO), indium zinc tin oxide (IZTO), indium gallium zinc oxide (IGZO), indium gallium tin oxide (IGTO), or indium gallium zinc tin oxide (IGZTO).

The gate insulating film 162 may be disposed on the semiconductor layer 120. The gate insulating film 162 may function as the gate insulating film of the transistor TR. The gate insulating film 162 may be formed as, for example, an inorganic layer including SiOₓ, SiNₓ, and SiOₓN_{y} or a stack of SiOₓ, SiNₓ, and/or SiOₓN_{y}.

A first conductive layer 140 may be disposed on the gate insulating film 162. The first conductive layer 140 may include a gate electrode GE of the transistor TR. The gate electrode GE may overlap the channel region of the active material layer ACT in the third direction DR3.

The first conductive layer 140 may be formed as a single layer or a multilayer including molybdenum (Mo), aluminum (Al), chromium (Cr), gold (Au), titanium (Ti), nickel (Ni), neodymium (Nd), copper (Cu), or an alloy thereof, but the disclosure is not limited thereto.

The interlayer insulating film 163 may be disposed on the first conductive layer 140. The interlayer insulating film 163 may be disposed to cover the first conductive layer 140 and function as an insulating film between the first conductive layer 140 and layers disposed on the first conductive layer 140. The interlayer insulating film 163 may be formed as, for example, multiple layers in which inorganic insulating layers including at least one of SiOₓ, SiNₓ, and SiOₓN_{y} are alternately stacked.

A second conductive layer 160 is disposed on the interlayer insulating film 163. The second conductive layer 160 may include a drain electrode SD1 and a source electrode SD2 of the transistor TR.

The drain electrode SD1 and the source electrode SD2 of the transistor TR may be electrically connected to both end portions of the active material layer ACT of the transistor TR (e.g., the doped regions of the active material layer ACT) through contact holes penetrating the interlayer insulating film 163 and the gate insulating film 162. The source electrode SD2 of the transistor TR may also be electrically connected to the lower metal layer 110 through a contact hole penetrating the interlayer insulating film 163, the gate insulating film 162, and the buffer layer 161.

The second conductive layer 160 may be formed as a single layer or as multiple layers including Mo, Al, Cr, Au, Ti, Ni, Nd, Cu, or an alloy thereof, but the disclosure is not limited thereto.

The passivation layer 164 is disposed on the second conductive layer 160. The passivation layer 164 may cover and protect the second conductive layer 160. The passivation layer 164 may be formed as, for example, a multilayer in which inorganic insulating layers including at least one of SiOₓ, SiNₓ, and SiOₓN_{y} are alternately stacked.

A third conductive layer 180 is disposed on the passivation layer 164. The third conductive layer 180 may include a first voltage line VL1, a second voltage line VL2, and a first conductive pattern CDP.

A high-potential voltage (or a first power supply voltage) to be supplied to the transistor TR may be applied to the first voltage line VL1, and a low-potential voltage (or a second power supply voltage), which is lower than the high-potential voltage (or the first power supply voltage), may be applied to the second voltage line VL2.

The first voltage line VL1 may be electrically connected to the transistor TR to supply the high-potential voltage (or the first power supply voltage) to the transistor TR. The first voltage line VL1 may be electrically connected to the drain electrode SD1 of the transistor TR through a contact hole penetrating the passivation layer 164.

The second voltage line VL2 may be electrically connected to a second electrode 220 to supply the low-potential voltage (or the second power supply voltage) to the second electrode 220. An alignment signal for aligning light-emitting elements ED may be applied to the second voltage line VL2 during the fabrication of the display device 10.

The first conductive pattern CDP may be electrically connected to the source electrode SD2 of the transistor TR through a contact hole penetrating the passivation layer 164. The first conductive pattern CDP may also be electrically connected to a first electrode 210. The first conductive pattern CDP may transmit the first power supply voltage, applied thereto from the first voltage line VL1, to the first electrode 210.

The third conductive layer 180 may be formed as a single layer or multiple layers including Mo, Al, Cr, Au, Ti, Ni, Nd, Cu, or an alloy thereof, but the disclosure is not limited thereto.

The via layer 165 is disposed on the third conductive layer 180. The via layer 165 may be disposed on the passivation layer 164 where the third conductive layer 180 is disposed. The via layer 165 may planarize a surface. The via layer 165 may include an organic insulating material such as, for example, polyimide (PI).

Referring to FIGS. 3 and 4, the light-emitting element layer may be disposed on the via layer 165. The light-emitting element layer may include the electrode layer 200, the first bank 400, the second bank 600, light-emitting elements ED, contact electrodes 700, first, second, and third insulating layers 510, 520, and 530, and a scattering layer 800.

The first bank 400 may be disposed on a first surface of the via layer 165. The first bank 400 may be disposed directly on the top surface of the via layer 165. The first bank 400 may be disposed in a first emission area EMA1.

The first bank 400 may extend in the second direction DR2 in the first emission area EMA1. The length, in the second direction DR2, of the first bank 400 may be smaller than the length, in the second direction DR2, of the first emission area EMA1, surrounded by the second bank 600.

The first bank 400 may include sub-banks (410 and 420), which are disposed in the first emission area EMA1 and are spaced apart from each other. The sub-banks (410 and 420) may extend in the second direction DR2 and may be spaced apart from each other in the first direction DR1. For example, the first bank 400 may include first and second sub-banks 410 and 420. The first sub-bank 410 may be disposed in a left part of the first emission area EMA1, in a plan view. The second sub-bank 420 may be spaced apart from the first sub-bank 410 in the first direction DR1 and may be disposed in a right part of the first emission area EMA1, in a plan view. Light-emitting elements ED may be disposed between the sub-banks (410 and 420), which are spaced apart from each other.

The first bank 400 may include inclined side surfaces and may change the travel direction of light emitted from the light-emitting elements ED from a direction toward the side surfaces of the first bank 400, into an upward direction (e.g., the display direction). The first bank 400 may provide space where the light-emitting elements ED are disposed and may function as a reflective barrier capable of changing the direction of the light emitted from the light-emitting elements ED so that the light travels in the display direction (the third direction DR3).

The first bank 400 is illustrated as having linearly inclined side surfaces, but the disclosure is not limited thereto. In other examples, the side surfaces (or the outer surfaces) of the first bank 400 may have a semicircular or semielliptical shape with a curvature. The first bank 400 may include an organic insulating material such as PI, but the disclosure is not limited thereto.

The electrode layer 200 may be disposed on the first bank 400 and parts of the via layer 165, exposed by the first bank 400. The electrode layer 200 may be disposed in each subpixel PXn to extend in a direction. The electrode layer 200 may extend in the second direction DR2 and may be disposed over the first emission area EMA1 and a first subarea SA1 of the first subpixel PX1. The electrode layer 200 may be disposed on the first bank 400 and the parts of the via layer 165, exposed by the first bank 400, in the first emission area EMA1, and may be disposed on the via layer 165, in a light-blocking area NEM of the first subpixel PX1.

The electrode layer 200 may include electrodes, which extend in the second direction DR2 and are spaced apart from each other in the first direction DR1. The electrode layer 200 may include first and second electrodes 210 and 220, which are spaced apart from each other. The first and second electrodes 210 and 220 may be disposed at least in part in the first emission area EMA. As will be described later, at least parts of the first and second electrodes 210 and 220 in the first emission area EMA1 may be exposed by the second bank 600.

In the first emission area EMA1, the first and second electrodes 210 and 220 may be disposed on the first and second sub-banks 410 and 420, respectively. The first and second electrodes 210 and 220 may be disposed at least on inclined side surfaces of the first and second sub-banks 410 and 420, respectively. The first and second electrodes 210 and 220 may be disposed to cover opposing side surfaces of the first and second sub-banks 410 and 420 and thus to reflect light emitted from the light-emitting elements ED.

The first electrode 210 may be electrically connected to the first conductive pattern CDP1 through a first electrode contact hole CTD, which penetrates the via layer 165. The first electrode 210 may be in contact with part of the top surface of the first conductive pattern CDP1, exposed by the first electrode contact hole CTD. The first electrode 210 may be electrically connected to the transistor TR through the first conductive pattern CDP1. The first electrode contact hole CTD is illustrated as overlapping with the second bank 600 in the third direction DR3, but the location of the first electrode contact hole CTD is not particularly limited.

The second electrode 220 may be electrically connected to the second voltage line VL2 through a second electrode contact hole CTS, which penetrates the via layer 165. The second electrode 220 may be in contact with part of the top surface of the second voltage line VL2, exposed by the second electrode contact hole CTS. The second electrode 220 may receive a second power supply voltage from the second voltage line VL2. The second electrode contact hole CTS is illustrated as overlapping with the second bank 600 in the third direction DR3, but the location of the second electrode contact hole CTS is not particularly limited.

The first and second electrodes 210 and 220 may be disposed in the first subpixel PX1 to extend in the second direction DR2, in a plan view, and may be separated from first and second electrodes 210 and 220 of a neighboring subpixel PXn, in the second direction DR2, of the first subpixel PX1, in a separation part ROP1 (refer to FIG. 3) of the first subarea SA1 (refer to FIG. 3) of the first subpixel PX1. The first and second electrodes 210 and 220, which are spaced apart from the first and second electrodes 210 and 220 of the neighboring subpixel PXn in the second direction DR2, may be obtained by forming electrode lines, which are for use in aligning the light-emitting elements ED, to extend in the second direction DR2 and dividing each of the electrode lines in the separation part ROP1 of the first subarea SA1 after the alignment of the light-emitting elements ED. The electrode lines may be used to form an electric field in the first subpixel PX1 to align the light-emitting elements ED during the fabrication of the display device 10.

The first and second electrodes 210 and 220 may be spaced apart from each other in the first direction DR1. As the first and second electrodes 210 and 220 are spaced apart from each other in the first direction DR1, the first and second electrodes 210 and 220 may expose part of the via layer 165. The gap between the first and second electrodes 210 and 220 may overlap with at least parts of the light-emitting elements ED. Thus, the first and second electrodes 210 and 220 may expose parts of the light-emitting elements ED in the downward direction.

The first and second electrodes 210 and 220 may be electrically connected to the light-emitting elements ED. The first and second electrodes 210 and 220 may be connected to both end portions of each of the light-emitting elements ED through first and second contact electrodes 710 and 720 and may transmit electric signals from the circuit element layer CCL to the light-emitting elements ED.

The electrode layer 200 may include a conductive material with high reflectance. For example, the electrode layer 200 may include a material with high reflectance such as a metal (e.g., silver (Ag), Cu, Al, Mo, or Ti) or an alloy of Al, Ni, or lanthanum (La). The light from the light-emitting elements ED that is emitted toward the side surfaces of the first bank 400 or the outer surfaces of the electrode layer 200 may be reflected in an upward direction of the first subpixel PX1 by the electrode layer 200. However, the disclosure is not limited to this, and the electrode layer 200 may further include a transparent conductive material. For example, the electrode layer 200 may include a material such as ITO, IZO, or ITZO. In some embodiments, the electrode layer 200 may have a structure in which one or more layers of a transparent conductive material and one or more layers of a metal with high reflectance are stacked or may be formed as a single layer including a transparent conductive material and a metal with high reflectance. For example, the electrode layer 200 may have a stack of ITO/Ag/ITO/, ITO/Ag/IZO, or ITO/Ag/ITZO/IZO.

The first insulating layer 510 may be disposed on the electrode layer 200. The first insulating layer 510 may be disposed to cover the electrode 200 and the parts of the via layer 165, exposed by the electrode layer 200. The first insulating layer 510 may include contacts exposing at least parts of the first and second electrodes 210 and 220. Contact electrodes 700 and the electrode layer 200 may be electrically connected through the contacts exposing at least parts of the first and second electrodes 210 and 220. The contacts of the first insulating layer 510 are illustrated as being disposed in the first emission area EMA1, but the disclosure is not limited thereto. Alternatively, the contacts of the first insulating layer 510 may be disposed in the first subarea SA1.

The first insulating layer 510 may protect the electrode layer 200 and may insulate the first and second electrodes 210 and 220. The first insulating layer 510 may prevent the light-emitting elements ED from directly contacting, other members below the light-emitting elements ED, and thereby preventing the light-emitting elements ED from being damaged by such contact. The first insulating layer 510 may include an inorganic insulating material.

The second bank 600 may be disposed on the first insulating layer 510. The second bank 600 may include parts extending in the first direction DR1 and parts extending in the second direction DR2 and may thus be arranged in a lattice pattern, in a plan view.

The second bank 600 may be disposed along the boundaries of the first subpixel PX1 to separate the first subpixel PX1 from other subpixels PXn and may define (or surround) the first emission area EMA1 and the first subarea SA1 of the first subpixel PX1. As the second bank 600 may have a greater height than the first bank 400 and thus may separate the first subpixel PX1 from other subpixels PXn, ink in which the light-emitting elements ED are dispersed can be properly sprayed into the first emission area EMA1 without being mixed with ink in other neighboring subpixels PXn, during an inkjet printing process for supplying and aligning the light-emitting elements ED as performed during the fabrication of the display device 10.

The second bank 600 may include an opening corresponding to the first emission area EMA1 of the first subpixel PX1 and may provide space in which to form a wavelength conversion layer WCL or a light-transmitting pattern TPL. The second bank 600 may include an organic insulating material such as, for example, PI, but the disclosure is not limited thereto.

The light-emitting elements ED may be disposed on the first insulating layer 510, in the first emission area EMA1. The light-emitting elements ED may be disposed between the first and second sub-banks 410 and 420. The light-emitting elements ED may be disposed on the first insulating layer 510 such that both end portions of each of the light-emitting elements ED may be positioned on the first and second electrodes 210 and 220, between the first and second sub-banks 410 and 420.

The light-emitting elements ED may be disposed to be spaced apart from one another in the direction in which the first and second electrodes 210 and 220 extend, i.e., in the second direction DR2, and may be aligned substantially to be parallel to each other. The light-emitting elements ED may extend in a direction, and the length of the light-emitting elements ED may be greater than the minimum distance between the first and second electrodes 210 and 220, which are spaced apart from each other in the first direction DR1. At least one end portion of each of the light-emitting elements ED may be disposed on one of the first and second electrodes 210 and 220, or both end portions of each of the light-emitting elements ED may be disposed on the first and second electrodes 210 and 220.

A second insulating layer 520 may be disposed on the light-emitting elements ED. The second insulating layer 520 may be disposed to surround at least parts of the outer surfaces of each of the light-emitting elements ED, but not to cover both end portions of each of the light-emitting elements ED. Thus, the width, in the first direction DR1, of the second insulating layer 520 may be smaller than the length, in the first direction DR1, of the light-emitting elements ED. Parts of the second insulating layer 520 on the light-emitting elements ED may extend in the second direction DR2 over the first insulating layer 510, in a plan view, and may thus form linear or island patterns in the first subpixel PX1. The second insulating layer 520 may protect and fix the light-emitting elements ED during the fabrication of the display device 10.

The contact electrodes 700 may be disposed on the second insulating layer 520. The contact electrodes 700 may include multiple contact electrodes spaced apart from each other. For example, the contact electrodes 700 may include the first and second contact electrodes 710 and 720, which are spaced apart from each other.

The first contact electrode 710 may be disposed on the first electrode 210 and the second insulating layer 520. The first contact electrode 710 may expose part of the top surface of the second insulating layer 520.

The first contact electrode 710 may extend in the second direction DR2. The first contact electrode 710 may electrically contact the first electrode 210 and the first end portions of the light-emitting elements ED. The first contact electrode 710 may electrically contact the first end portions of the light-emitting elements ED, exposed by the second insulating layer 520, in the first emission area EMA1. Also, the first contact electrode 710 may electrically contact part of the first electrode 210, exposed by a contact penetrating the first insulating layer 510. As the first contact electrode 710 contacts the first end portions of the light-emitting elements ED and with the first electrode 210, the first contact electrode 710 may electrically connect the light-emitting elements ED and the first electrode 210.

A third insulating layer 530 may be disposed on the first contact electrode 710. The third insulating layer 530 may be disposed on the first contact electrode 710 to cover the first contact electrode 710. The third insulating layer 530 may insulate the first and second contact electrodes 710 and 720. The third insulating layer 530 may cover the first contact electrode 710 and may be aligned in parallel with a sidewall of the second insulating layer 520. The sidewall of the second insulating layer 520 that the third insulating layer 530 is aligned in parallel with may be a sidewall of the second insulating layer 520 that faces the second sub-bank 420.

The second contact electrode 720 may be disposed on the second electrode 220. The second contact electrode 720 may be disposed on the second electrode 220 and the third insulating layer 530.

The second contact electrode 720 may extend in the second direction DR2. The second contact electrode 720 may electrically contact the second electrode 220 and the second end portions of the light-emitting elements ED. The second contact electrode 720 may electrically contact the second end portions of the light-emitting elements ED, exposed by the second and third insulating layers 520 and 530, in the first emission area EMA1. Also, the second contact electrode 720 may electrically contact part of the second electrode 220, exposed by a contact penetrating the first insulating layer 510. As the second contact electrode 720 electrically contacts the second end portions of the light-emitting elements ED and with the second electrode 220, the second contact electrode 720 may electrically connect the light-emitting elements ED and the second electrode 220.

The first end portions of the light-emitting elements ED, exposed by the second insulating layer 520, may be electrically connected to the first electrode 210 through the first contact electrode 710, and the second end portions of the light-emitting elements ED, exposed by the second and third insulating layers 520 and 530, may be electrically connected to the second electrode 220 through the second contact electrode 720.

The first and second contact electrodes 710 and 720 are illustrated as being formed in different layers with the third insulating layer 530 interposed therebetween, but the disclosure is not limited thereto. In other examples, the first and second contact electrodes 710 and 720 may be formed in substantially the same layer and may be spaced apart from each other by the second insulating layer 520, and the third insulating layer 530 may not be provided.

The contact electrodes 700 may include a conductive material. For example, the contact electrodes 700 may include ITO, IZO, ITZO, or Al. For example, the contact electrodes 700 may include a transparent conductive material, and light emitted from the light-emitting elements ED may travel toward the first and second electrodes 210 and 220 through the contact electrodes 700 and may be reflected by the outer surfaces of each of the first and second electrodes 210 and 220.

The wavelength conversion layer WCL or the light-transmitting pattern TPL may be disposed in an area defined (surrounded) by the second bank 600. The wavelength conversion layer WCL or the light-transmitting pattern TPL may be disposed in an opening of the second bank 600, exposing the light-emitting elements ED. The wavelength conversion layer WCL or the light-transmitting pattern TPL may be fill part of the opening of the second bank 600. The wavelength conversion layer WCL or the light-transmitting pattern TPL may contact the side surfaces of the second bank 600.

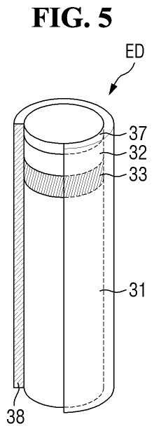

FIG. 5 is a perspective view of a light-emitting element according to an embodiment of the disclosure.

Referring to FIG. 5, the light-emitting element ED, which is a particulate element, may have a rod- or cylindrical shape with a selected aspect ratio. The length of the light-emitting element ED may be greater than the diameter of the light-emitting element ED, and the aspect ratio of the light-emitting element ED may be in a range of about 6:5 to about 100:1. However, the disclosure is not limited to this.

The light-emitting element ED may have a nanometer-scale size of about 1 nm to about 1 μm or a micrometer-scale size of about 1 μm to about 1 mm. For example, the diameter and the length of the light-emitting element ED may both be at a nanometer scale or at a micrometer scale. In another example, the diameter of the light-emitting element ED may be in a nanometer scale, but the length of the light-emitting element ED may be in a micrometer scale. In another example, in case that there are multiple light-emitting elements ED, some of the light-emitting elements ED may have a nanometer-scale diameter and/or length, and some of the light-emitting elements ED may have a micrometer-scale diameter and/or length.

For example, the light-emitting element ED may be an inorganic light-emitting diode. The inorganic light-emitting diode may include multiple semiconductor layers. For example, the inorganic light-emitting diode may include a semiconductor layer of a first conductivity type (e.g., an n-type), a semiconductor layer of a second conductivity type (e.g., a p-type), and an active semiconductor layer interposed between the semiconductor layer of the first conductivity type and the semiconductor layer of the second conductivity type. The active semiconductor layer may receive holes and electrons from the semiconductor layer of the first conductivity type and the semiconductor layer of the second conductivity type, respectively, and the holes and the electrons may combine together in the active semiconductor layer. As a result, the light-emitting element ED may emit light.

For example, the semiconductor layers of the light-emitting element ED may be sequentially stacked in the length direction of the light-emitting element ED. As illustrated in FIG. 5, the light-emitting element ED may include a first semiconductor layer 31, a device active layer 33, and a second semiconductor layer 32, which are sequentially stacked in the length direction of the light-emitting element ED. The first semiconductor layer 31, the device active layer 33, and the second semiconductor layer 32 may be the semiconductor layer of the first conductivity type, the active semiconductor layer, and the semiconductor layer of the second conductivity type, respectively.

The first semiconductor layer 31 may be doped with a dopant of the first conductivity type. The dopant of the first conductivity type may be Si, Ge, or Sn. For example, the first semiconductor layer 31 may be n-GaN doped with an n-type dopant such as Si.

The second semiconductor layer 32 may be spaced apart from the first semiconductor layer 31 by the device active layer 33. The second semiconductor layer 32 may be doped with a dopant of the second conductivity type. For example, the second semiconductor layer 32 may be p-GaN doped with a p-type dopant such as Mg.

The device active layer 33 may include a material having a single- or multi-quantum well structure. As described above, as electrical signals are applied through the first and second semiconductor layers 31 and 32, the device active layer 33 may emit light due to the combination of electron-hole pairs.

In an embodiment, the device active layer 33 may have a structure in which a semiconductor material having large bandgap energy and a semiconductor material having small bandgap energy are alternately stacked, and may include different group-III, group-IV, and group-IV semiconductor materials depending on the wavelength of light to be emitted.

Light may be emitted from the device active layer 33 not only through both end surfaces, in the length direction, of the light-emitting element ED, but also through the outer circumference surface (or the outer surface or the side surface) of the light-emitting element ED. The direction in which light is emitted from the device active layer 33 is not particularly limited. Thus, light emitted from an array of light-emitting elements ED aligned on the first surface of the substrate SUB can travel not only in directions away from both end surfaces of the array of light-emitting elements ED, but also in upward and downward directions.

The light-emitting element ED may further include a device electrode layer 37. The device electrode layer 37 may contact the second semiconductor layer 32. The device electrode layer 37 may be an ohmic contact electrode, but the disclosure is not limited thereto. In other embodiments, the device electrode layer 37 may be a Schottky contact electrode.

When both end portions of the light-emitting element ED and electrodes are electrically connected to a contact electrode 700, and electrical signals may be applied to the first and second semiconductor layers 31 and 32, the device electrode layer 37 may be disposed between the second semiconductor layer 32 and the electrodes. The device electrode layer 37 may reduce resistance. The device electrode layer 37 may include at least one of Al, Ti, indium (In), Au, Ag, ITO, IZO, and indium tin zinc oxide (ITZO). The device electrode layer 37 may include a semiconductor material doped with an n-type or a p-type dopant.

The light-emitting element ED may further include a device insulating film 38, which surrounds the outer circumferential surfaces of the first semiconductor layer 31, the second semiconductor layer 32, the device active layer 33, and/or the device electrode layer 37. The device insulating film 38 may surround the outer surfaces of at least the device active layer 33 and may extend in the direction in which the light-emitting element ED extends. The device insulating film 38 may protect the first semiconductor layer 31, the second semiconductor layer 32, the device active layer 33, and/or the device electrode layer 37. As the device insulating film 38 may include an insulating material, the device insulating film 38 can prevent short circuits that may occur when the light-emitting element ED contacts an electrode through which electrical signals are transmitted. As the device insulating film 38 protects the outer circumferential surfaces of the first and second semiconductor layers 31 and 32, as well as the outer circumferential surface of the device active layer 33, the device insulating film 38 can prevent degradation of emission efficiency.

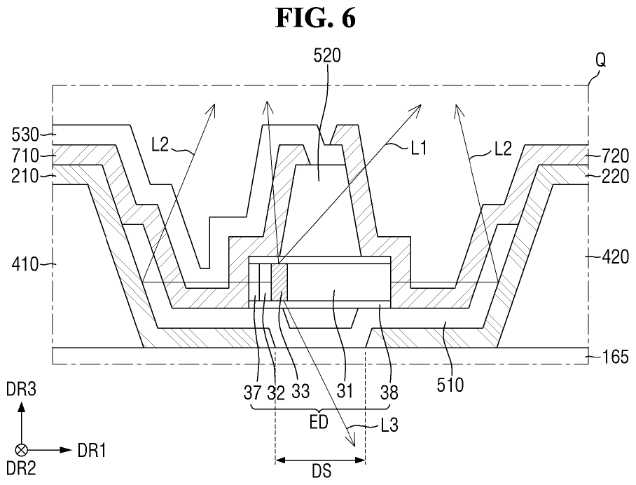

FIG. 6 is an enlarged schematic cross-sectional view of an area Q of FIG. 4.

FIG. 6 illustrates how light emitted from a light-emitting element ED that is aligned on the via layer 165 may travel.

Referring to FIGS. 5 and 6, the light-emitting element ED may extend in parallel to the first surface (or the top surface) of the substrate SUB. Semiconductor layers of the light-emitting element ED may be sequentially arranged in a parallel direction with respect to the top surface of the substrate SUB. For example, in the light-emitting element ED, a first semiconductor layer 31, a device active layer 33, and a second semiconductor layer 32 may be sequentially arranged in parallel to the top surface of the substrate SUB.

In a cross-sectional view taken from the first end portion to the second end portion of the light-emitting element ED, which is aligned on the first surface of the substrate SUB, the first semiconductor layer 31, the device active layer 33, the second semiconductor layer 32, and the device electrode layer 37 may be sequentially formed in a parallel direction with respect to the top surface of the substrate SUB.

The light-emitting element ED (at least one light-emitting element ED) may be disposed such that the first and second end portions of the light-emitting element ED may be placed on the first and second electrodes 210 and 220, respectively. The device electrode layer 37 or the second semiconductor layer 32 may be disposed in the first end portion of the light-emitting element ED on the first electrode 210, and the first semiconductor layer 31 may be disposed in the second end portion of the light-emitting element ED on the second electrode 220. However, the disclosure is not limited to this. In other embodiments, the first semiconductor layer 31 may be disposed in the first end portion of the light-emitting element ED, and the device electrode layer 37 or the second semiconductor layer 32 may be disposed in the second end portion of the light-emitting element ED.

In a cross-sectional view taken across both end portions of the light-emitting element ED, which is aligned on the first surface of the substrate SUB, the device insulating film 38 may be disposed on the top surfaces and the bottom surfaces of the first semiconductor layer 31, the second semiconductor layer 32, the device active layer 33, and the device electrode layer 37.

The light-emitting element ED may be aligned such that both end portions thereof may face the first and second sub-banks 410 and 420, between the first and second sub-banks 410 and 420. The first end portion of the light-emitting element ED may be positioned on the first electrode 210, which is disposed on part of the first surface of the via layer 165, exposed by the first sub-bank 410, and the second end portion of the light-emitting element ED may be positioned on the second electrode 220, which is disposed on part of the first surface of the via layer 165, exposed by the second sub-bank 420.

The first electrode 210 may extend from the side surface of the first sub-bank 410 to the outside and may thus be disposed in part between the first and second sub-banks 410 and 420. The first electrode 210 may be disposed in part on a portion of the top surface of the via layer 165, exposed by the first and second sub-banks 410 and 420, between the first and second sub-banks 410 and 420.

The second electrode 220 may extend from the side surface of the second sub-bank 420 to the outside and may thus be disposed in part between the first and second sub-banks 410 and 420. The second electrode 220 may be disposed in part on the portion of the top surface of the via layer 165, exposed by the first and second sub-banks 410 and 420, between the first and second sub-banks 410 and 420.

The first and second electrodes 210 and 220 may be spaced apart from each other in the first direction DR1, on the via layer 165 in the gap between the first and second sub-banks 410 and 420. A gap region DS, where the first and second electrodes 210 and 220 are spaced apart from each other and face each other, may expose at least part of the first surface of the via layer 165.

The light-emitting element ED may not overlap at least a part of the first and second electrodes 210 and 220 in the third direction DR3. The first and second electrodes 210 and 220 may expose at least part of the light-emitting element ED in the downward direction.

For example, the first end portion of the light-emitting element ED may overlap the first electrode 210 in the third direction DR3, the second end portion of the light-emitting element ED may overlap the second electrode 220 in the third direction DR3, but the light-emitting element ED between the first and second end portions may not overlap either the first electrode 210 or the second electrode 220 in the third direction DR3. The first electrode 210 may be disposed to cover the first end portion of the light-emitting element ED from below the light-emitting element ED. The second electrode 220 may be disposed to cover the second end portion of the light-emitting element ED from below the light-emitting element ED. The first and second electrodes 210 and 220 may be disposed not to cover at least part of the light-emitting element ED from below the light-emitting element ED. Thus, at least part of the light-emitting element ED between the first and second electrodes 210 and 220 may be exposed in the downward direction by the first and second electrodes 210 and 220, which are spaced apart from each other.

The first and second electrodes 210 and 220 are illustrated as covering the first and second end portions, respectively, of the light-emitting element ED, from below the light-emitting element ED, but the disclosure is not limited thereto. In other embodiments, the first electrode 210 may cover the first end portion of the light-emitting element ED, from below the light-emitting element ED, but the second electrode 220 may not cover the light-emitting element ED. The second electrode 220 may cover the second end portion of the light-emitting element ED, from below the light-emitting element ED, and the first electrode 210 may not cover the light-emitting element ED. In another example, neither of the first and second electrodes 210 and 220 may cover the light-emitting element ED from below the light-emitting element ED. The first and second electrodes 210 and 220 may not overlap with the light-emitting element ED in the third direction DR3.

The second insulating layer 520 may be disposed on the light-emitting element ED. The second insulating layer 520 may surround outer surfaces of the light-emitting element ED (for example, the device insulating film 38 of the light-emitting element ED). The second insulating layer 520 may surround the outer surfaces of the light-emitting element ED, in a region where the light-emitting element ED is disposed. The second insulating layer 520 may be disposed on the first insulating layer 510, in a region where the light-emitting element ED is not disposed.

The first contact electrode 710 may contact the first end portion of the light-emitting element ED exposed by the second insulating layer 520. The first contact electrode 710 may surround the outer surfaces and an end surface of the light-emitting element ED, exposed by the second insulating layer 520. The first contact electrode 710 may contact the device insulating film 38 and the device electrode layer 37 of the light-emitting element ED.

The second contact electrode 720 may contact the second end portion of the light-emitting element ED, exposed by the second and third insulating layers 520 and 530. The second contact electrode 720 may be disposed to surround outer surfaces and an end surface of the light-emitting element ED, exposed by the second and third insulating layers 520 and 530. The second contact electrode 720 may contact the device insulating film 38 and the first semiconductor layer 31 of the light-emitting element ED.

The light-emitting element ED, which is aligned on the substrate SUB, may emit light in accordance with electric signals applied through the first and second contact electrodes 710 and 720. The device active layer 33 of the light-emitting element ED may generate light in response to electric signals, and the direction that the light generated by the device active layer 33 may travel is not particularly limited, and may be random.

For example, the light generated by the device active layer 33 of the light-emitting element ED may include first light L1, second light L2, and third light L3, where the light-emitting element ED is aligned between the first and second electrodes 210 and 220, in a cross-sectional view of the display device 10. The first light L1 may travel in an upward direction from the device active layer 33, the second light L2 may travel in a lateral direction from the device active layer 33, and the third light L3 may travel in a downward direction from the device active layer 33.

The first light L1 may be generated by the device active layer 33 of the light-emitting element ED and may be emitted through the device insulating film 38 of the light-emitting element ED that is disposed above the first and second semiconductor layers 31 and 32. The first light L1 may travel in the display direction of the display device 10, i.e., in the upward direction from the light-emitting element ED. The first light L1 may be incident upon the wavelength conversion layer WCL or the light-transmitting pattern TPL.

The second light L2 may be generated by the device active layer 33 of the light-emitting element ED and may be emitted through both of the end surfaces of the light-emitting element ED. Some of the second light L2 emitted through an end surface of the light-emitting element ED may be reflected by part of the first electrode 210 on the side surface of the first sub-bank 410 and may travel in the upward direction. Similarly, some of the second light L2 emitted through the other end surface of the light-emitting element ED may be reflected by part of the second electrode 220 on the side surface of the second sub-bank 420 and may travel in the upward direction. Most of the second light L2, emitted through both end surfaces of the light-emitting elements ED, may be reflected by the first and second electrodes 210 and 220 on the first bank 400 and may thus travel in the upward direction.

The third light L3 may be generated by the device active layer 33 of the light-emitting element ED and may be emitted from the light-emitting element ED through part of the device insulating film 38 of the light-emitting element ED that is disposed below the first and second semiconductor layers 31 and 32, in a cross-sectional view. The third light L3 may travel in the downward direction from the light-emitting element ED, i.e., in the opposite direction of the display direction of the display device 10.

Some of the third light L3 may travel into the gap region DS between the first and second electrodes 210 and 220. In the gap region DS, the electrode layer 200 (the first and second electrodes 210 and 220) may not be disposed. Thus, the third light L3 may not be able to be reflected by the first and second electrodes 210 and 220 and may thus travel in the downward direction of the display device 10.

Since the direction in which light emitted from the light-emitting element ED is output is not particularly limited, the emitted light may travel in an upward, lateral, or downward direction from the light-emitting element ED, and some of the light traveling in the downward direction from the light-emitting element ED may enter the gap region DS between the first and second electrodes 210 and 220 and may continue to travel in the downward direction without changing its direction.

FIG. 6 illustrates that all of the third light L3 travels toward the gap region DS, but the traveling direction of the third light L3 is not particularly limited. In other examples, some of the third light L3 may be incident upon the top surfaces of parts of the first and second electrodes 210 and 220 overlapping the end portions of the light-emitting element ED. Some of the third light L3 may be reflected by the first and second electrodes 210 and 220 in the upward direction.

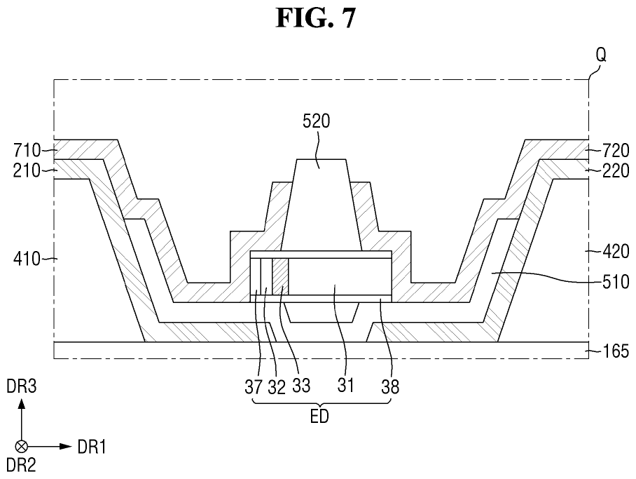

FIG. 7 is an enlarged schematic cross-sectional view of the area Q of FIG. 4.

The embodiment of FIG. 7 differs from the embodiment of FIG. 6 in that the first and second contact electrodes 710 and 720 are formed in the same layer, and that the third insulating layer 530 Is not provided.

Referring to FIG. 7, the first and second contact electrodes 710 and 720 may be disposed directly on the second insulating layer 520. The first and second contact electrodes 710 and 720 may be formed in the same layer. The first and second contact electrodes 710 and 720 may include the same material. The first and second contact electrodes 710 and 720 may be formed at the same time by a single mask process. Thus, as an additional mask process for forming the first and second contact electrodes 710 and 720 is not needed, the efficiency of the fabrication of the display device 10 can be improved.

The first and second contact electrodes 710 and 720 may be spaced apart from each other by the second insulating layer 520. The first and second contact electrodes 710 and 720 may expose at least part of the top surface of the second insulating layer 520.

The embodiment of FIG. 7 is almost the same as the embodiment of FIG. 6 except that the third insulating layer 530 is not provided, and thus, a detailed description thereof will be omitted.

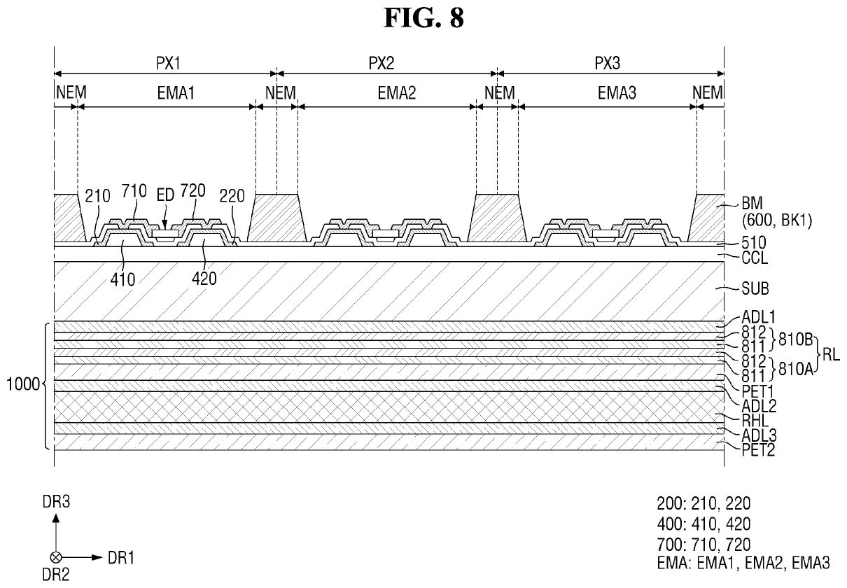

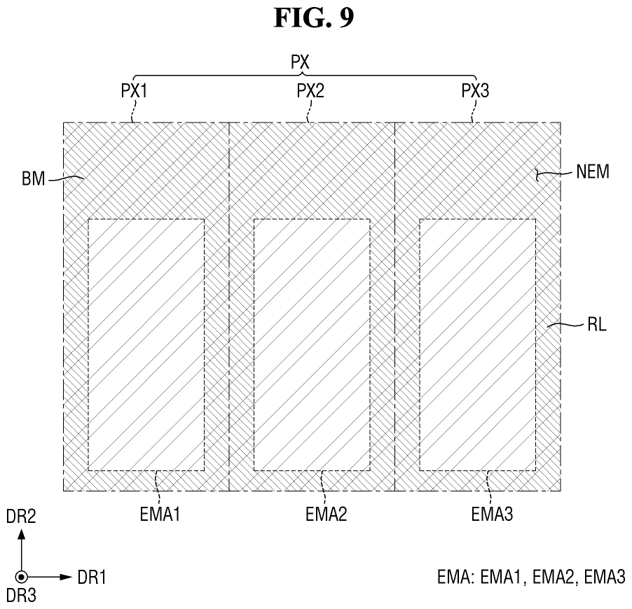

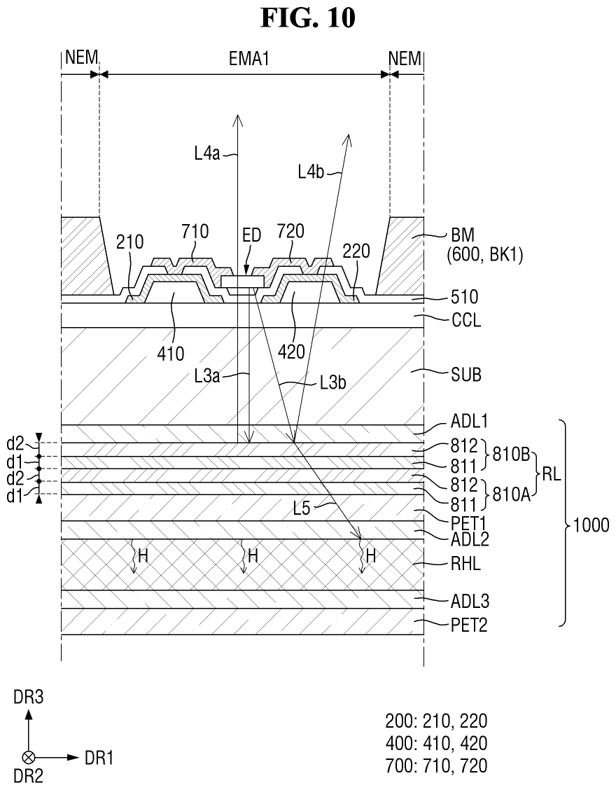

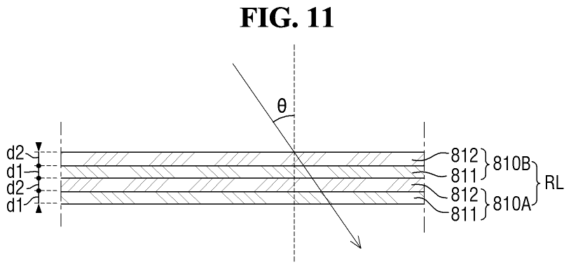

FIG. 8 is a schematic cross-sectional view of a display device according to an embodiment of the disclosure. FIG. 9 is a schematic layout view illustrating the arrangement of a light-blocking member and a second functional layer of the display device of FIG. 8 relative to each other. FIG. 10 is a schematic cross-sectional view illustrating how light emitted from light-emitting elements of the display device of FIG. 8 travels in a downward direction. FIG. 11 is a schematic cross-sectional view of a second functional layer according to an embodiment of the disclosure.

Referring to FIGS. 8 and 9, a functional layer 1000 may include a first functional layer RHL, a second functional layer RL, first and second passivation layers PET1 and PET2, and first, second, and third adhesive members ADL1, ADL2, and ADL3.

The second functional layer RL may be disposed on a second surface of a substrate SUB. The second functional layer RL may include emission areas EMA and may be disposed in an entire display area DPA. The second functional layer RL may be disposed in the emission areas EMA and light-blocking areas NEM. The second functional layer RL may overlap multiple arrays of light-emitting elements ED, which are disposed in the emission areas EMA, and a light-blocking member BM in a third direction DR3. The light-blocking member BM may include a second bank 600 or a first light-blocking member BK1 of a display panel 2000. Thus, the second functional layer RL may overlap the second bank 600 or the first light-blocking member BK1 in the third direction DR3.

The second functional layer RL may be attached to the bottom surface of the substrate SUB via the first adhesive member ADL1. The second functional layer RL may be a reflective layer reflecting light leaking out of the display panel 2000 in a downward direction.

The first functional layer RHL may be disposed below the second functional layer RL. The first functional layer RHL may be a heat dissipation layer. The first passivation layer PET1 may be disposed above the first functional layer RHL, and the second passivation layer PET2 may be disposed below the first functional layer RHL.

The first passivation layer PET1 may be disposed between the first and second functional layers RHL1 and RL. The first passivation layer PET1 may be attached to the top surface of the first functional layer RHL via the second adhesive member ADL2. The first passivation layer PET1 may be disposed on the bottom surface of the second functional layer RL.

The first passivation layer PET1 may protect the display panel 2000 and the second functional layer RHL. The first passivation layer PET1 may include a transparent polymer film. The transparent polymer film may include at least one of polyacrylate (PA), polyethylene terephthalate (PET), polyethylene naphthalate (PEN), polyether sulfone (PES), PI, polyarylate (PAR), polycarbonate (PC), polymethyl methacrylate (PMMA), and a cycloolefin copolymer (COC).

The second passivation layer PET2 may be disposed below the first functional layer RHL. The second passivation layer PET2 may be attached to the bottom surface of the first functional layer RHL via the third adhesive member ADL3.

The second passivation layer PET2 may protect the layers disposed above it. The second passivation layer PET2 may include at least one of the materials included in the first passivation layer PET1.

Referring to FIGS. 8 through 11, the second functional layer RL may include at least one optical layer in which multiple inorganic films having different refractive indexes are stacked. The second functional layer RL may be a Distributed Bragg Reflector (DBR) layer. The second functional layer RL may have a structure in which optical layers, each including multiple inorganic films having different refractive indexes, are stacked.

For example, the second functional layer RL may include first and second optical layers 810A and 810B. The second optical layer 810B may be stacked on the first optical layer 810A.

Each of the first and second optical layers 810A and 810B may include first and second inorganic films 811 and 812, and the first and second inorganic films 811 and 812 may have first and second refractive indexes, respectively, which are different from each other. The first optical layer 810A may include a first inorganic film 811 having a first refractive index n1 and a second inorganic film 812 having a second refractive index n2. The value of the second refractive index n2 and the value of the first refractive index n1 may be different. The second inorganic film 812 may be disposed on the first inorganic film 811.

The second optical layer 810B may include a first inorganic film 811 having the first refractive index n1 and a second inorganic film 812 having the second refractive index n2.

The second functional layer RL may have a structure in which first inorganic films 811 having the first refractive index n1 and second inorganic films 812 having the second refractive index n2 are alternately stacked.

FIG. 11 illustrates that the second functional layer RL may have a structure in which two first inorganic films 811 and two second inorganic films 812 are alternately stacked. The first inorganic film 811 and the second inorganic film 812 may have a different refractive indexes. However, the disclosure is not limited thereto. In other examples, the second functional layer RL may include more than one pair of optical layers, and each of the optical layers may include a stack of three or more inorganic films that may have different refractive indexes.

The first inorganic films 811 and the second inorganic films 812 of the second functional layer RL may include a transparent insulating material. For example, the transparent insulating material may include SiOₓ, SiNₓ, SiOₓN_{y}, or titanium oxide (TiOₓ). For example, the first inorganic films 811 may include, but are not limited to, SiNₓ, and the second inorganic films 812 may include, but are not limited to, SiOₓ.

The second functional layer RL may transmit some of incident light through itself and reflect some of the incident light, depending on the incidence angle of the light, emitted from the light-emitting elements ED and traveling in the downward direction through the gap region DS between first and second electrodes 210 and 220. As the second functional layer RL is formed by alternately stacking the first inorganic films 811 and the second inorganic films 812, which have a different refractive index from the first inorganic films 711, to repeatedly generate a change in refractive index, the transmittance of light incident upon the second functional layer RL varies depending on the incidence angle of the light. The reflectance of light incident upon the second functional layer RL can be controlled depending on the incidence angle of the light by controlling the materials and thicknesses of the first inorganic films 811 and the second inorganic films 812 and the number of inorganic films included in the second functional layer RL.

For example, the thicknesses of the first inorganic films 811 and the second inorganic films 812 may be controlled depending on the wavelength and the refractive index of light, to maximize the reflectance of light incident upon the second functional layer RL. If the refractive index of refractive layers (or inorganic films) is n and light to be reflected has a wavelength of λ₁, light having a wavelength of λ₁ can be effectively reflected by alternately stacking low- and high-refractive layers with a thickness of (λ₁)/(4n).

The transmittance (or reflectance) of light incident upon the second functional layer RL may vary depending on the incidence angle of the light. For example, in a case where the arrays of light-emitting elements ED emit blue light having a peak wavelength of about 445 nm to about 480 nm, the first refractive index n1 of the first inorganic films 811 and the wavelength of light emitted from the arrays of light-emitting elements ED, i.e., λ₁, may both be determined to be about 445 nm to about 480 nm, and as a result, a thickness d1 of the first inorganic films 811 may be determined to be (λ₁)/(4n1). Also, the second refractive index n2 of the second inorganic films 812 and the wavelength of light emitted from the arrays of light-emitting elements ED, i.e., λ₁, may both be determined to be about 445 nm to about 480 nm, and as a result, a thickness d2 of the second inorganic films 812 may be determined to be (λ₁)/(4n2).

Referring to FIG. 10, the second functional layer RL may reflect some of light (L3a and L3b) incident thereupon after being emitted from the arrays of light-emitting elements ED to travel in the downward direction.

Light incident upon a gap region between the first and second electrodes 210 and 220 from light-emitting elements ED may travel in the downward direction and may be incident upon the second functional layer RL. The light incident upon the second functional layer RL, i.e., the light (L3a and L3b), may be either reflected by or transmitted through the second functional layer RL, depending on the angle at which the light is incident upon the top surface of the second inorganic film 812 of the second optical layer 810B of the second functional layer RL. For example, some of the light (L3a and L3b) may be totally reflected due to the difference in refractive index between the first inorganic films 811 and the second inorganic films 812 and may thus travel in a display direction as light (L4a and L4b), and some of the light (L3a and L3b) may be transmitted through the first and second optical layers 810A and 810B, depending on its incidence angle, and may thus be incident upon the first functional layer RHL as light L5.

As the light incident upon the second functional layer RL from the light-emitting elements ED generally travels in the downward direction through the gap region between the first and second electrodes 210 and 220, the angle at which light is incident upon the second functional layer RL may be within a selected range. Thus, as the incidence angle of light is designed to be 0°, the thickness d1 of the first inorganic films 811 and the thickness d2 of the second inorganic films 812 may be determined to be (λ₁)/(4n1) or (λ₁)/(4n2).

The first functional layer RHL may release heat H generated by the display panel 2000.

The second functional layer RL, which is the reflective layer RL, may be disposed between the first functional layer RHL, which is the heat dissipation layer RHL, and the substrate SUB. The second functional layer RL may be disposed in a first emission area EMA1 where light-emitting elements ED are disposed, and may cover the light-emitting elements ED, from below the light-emitting elements ED, in the third direction DR3. The second functional layer RL may reflect at least some light leaked in the downward direction through the gap region between the first and second electrodes 210 and 220, among beams of light that are emitted from the light-emitting elements ED and travel in random directions. The second functional layer RL may be a reflective layer capable of reflecting light. For example, the second functional layer RL may be a DBR layer in which multiple inorganic films having different refractive indexes are alternately stacked. The reflectance or transmittance of light incident upon the top surface of the second functional layer RL may vary depending on the incidence angle of the light. As the reflective layer RL is disposed between the heat dissipation layer RHL and the substrate SUB, the traveling direction of light leaked in the downward direction of a display device 10 can be changed into the display direction of the display device 10, and as a result, the emission efficiency of the display device 10 can be improved.

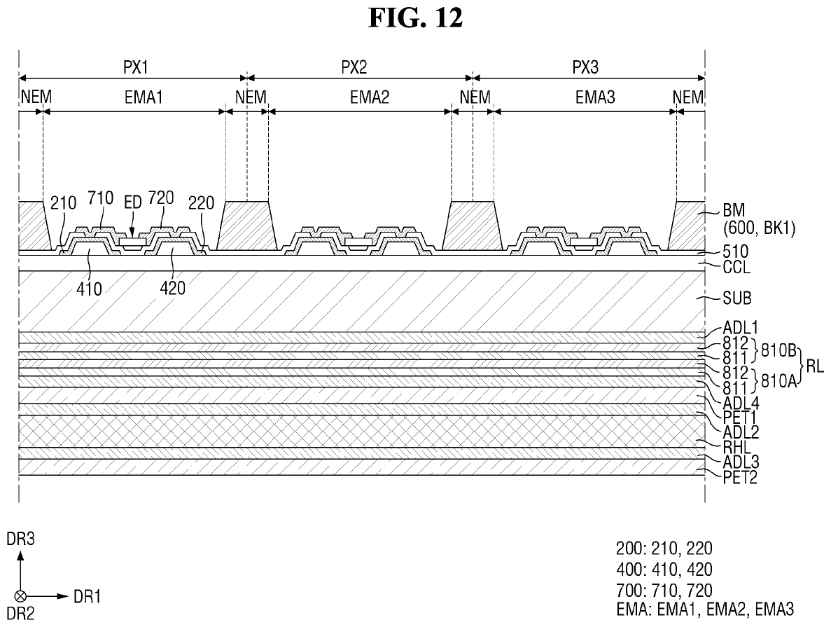

FIG. 12 is a schematic cross-sectional view of a display device according to an embodiment of the disclosure.

The embodiment of FIG. 12 differs from the embodiment of FIG. 8 in that first and second functional layers RHL and RL are fabricated separately and are attached to each other via a fourth adhesive member ADL4.

Referring to FIG. 12, the fourth adhesive member ADL4 may be disposed between the first and second functional layers RHL and RL. The fourth adhesive member ADL4 may bond a first passivation layer PET1, which is attached on the top surface of the second functional layer RL via a second adhesive member ADL2, and the first function layer RHL together. The fourth adhesive member ADL4 may be disposed between the first passivation layer PET1 and a first inorganic film 811 of a first optical layer 810A of the second functional layer RL, and the first passivation layer PET1 may be attached to the first inorganic film 811 of the first optical layer 810A of the second functional layer RL.

In the embodiment of FIG. 12, as the first and second functional layers RHL and RL are fabricated separately and are disposed in emission areas EMA of a display panel 2000, the design of the second functional layer RL on the first functional layer RHL can be easily changed in accordance with the layout of the emission areas EMA of the display panel 2000. Thus, the efficiency of the fabrication of a display device 10 can be improved.

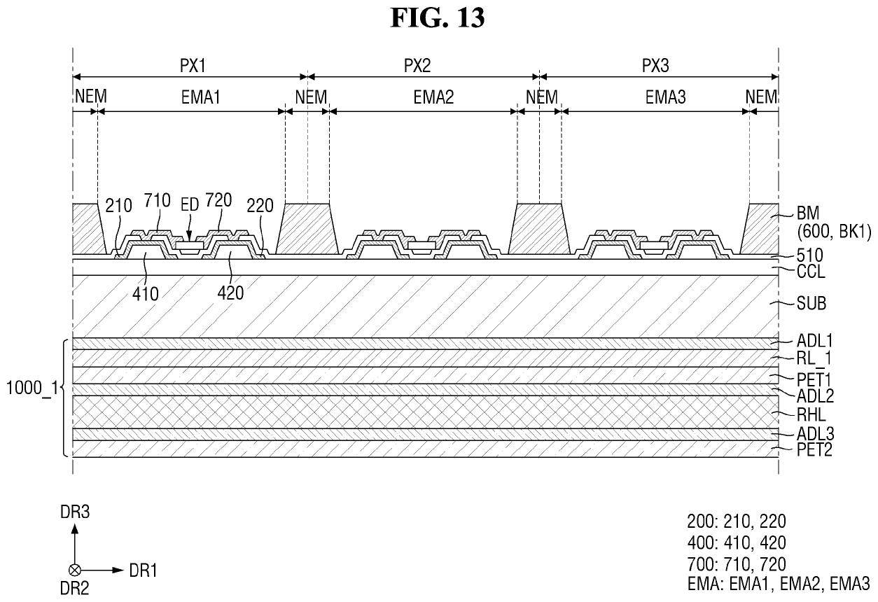

FIG. 13 is a schematic cross-sectional view of a display device according to an embodiment of the disclosure.

The embodiment of FIG. 13 differs from the embodiment of FIG. 8 in that a second functional layer RL_1 of a functional layer 1000_1 is a reflective layer including a reflective material.

Referring to FIG. 13, the second functional layer RL_1 may include a reflective film and/or a reflective sheet. In a case where the second functional layer RL_1 includes a reflective film and/or a reflective sheet, the second functional layer RL_1 may include a reflective material. For example, the second functional layer RL_1 may include a metal-based material such as Ag, Cu, Al, Ni, La, or a combination thereof or ITO, IZO, or ITZO, but the disclosure is not limited thereto.

In this example, as the second functional layer RL_1, which includes a reflective material, is disposed below a display panel 2000, light emitted from arrays of light-emitting elements ED to travel in the downward direction of a display device 10 may be reflected by the second functional layer RL_1 and may thus travel in an upward direction. Light incident upon the top surface of the second functional layer RL_1 from the arrays of light-emitting elements ED may be reflected by the top surface of the second functional layer RL_1 and may thus travel in the display direction of the display device 10. Thus, light leaked in the downward direction of the display device 10 through a gap region between first and second electrodes 210 and 220 can be reflected into the display direction of the display device 10, and as a result, the emission efficiency of the display device 10 can be improved.

Also, in a case where the second functional layer RL_1 includes a reflective film or a reflective sheet including a reflective material, a high-reflectance metallic material included in the second functional layer RL_1 may have high thermal conductivity. Thus, the second functional layer RL_1 can release heat generated by the display panel 2000, together with the first functional layer RHL.

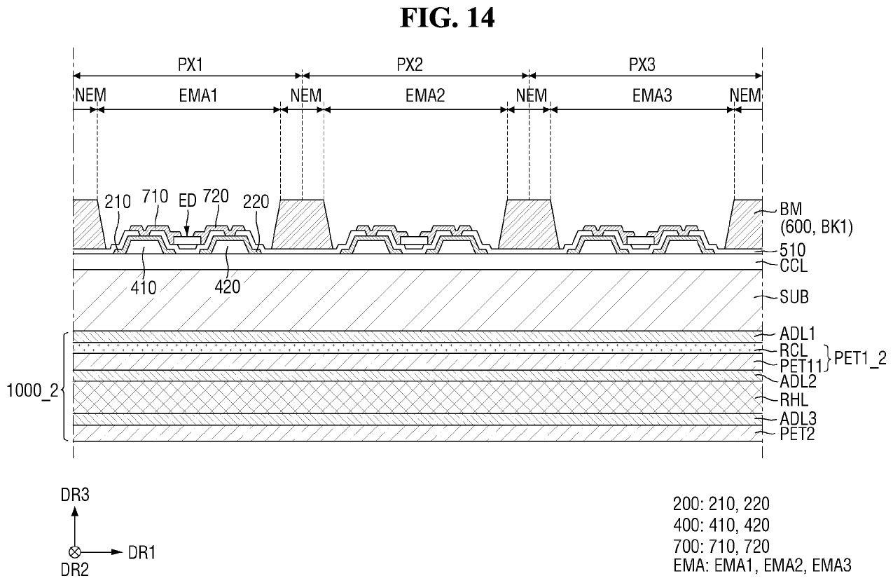

FIG. 14 is a schematic cross-sectional view of a display device according to an embodiment of the disclosure.

The embodiment of FIG. 14 differs from the embodiment of FIG. 8 in that a functional layer 1000_2 does not include a second functional layer RL, and that a first passivation layer PET1_2 includes a first layer PET11 and a reflective coating layer RCL, which is coated on the first layer PET11.

Referring to FIG. 14, the first passivation layer PET1_2 may be disposed between first and second adhesive members ADL1 and ADL2. The first passivation layer PET1_2 may be attached to the bottom surface of a substrate SUB by the first adhesive member ADL1, and a first functional layer RHL may be attached to the bottom surface of the first passivation layer PET1_2 by the second adhesive layer ADL2.

The first passivation layer PET1_2 may include the first layer PET11 and the reflective coating layer RCL, which is coated on the first layer PET11. The first layer PET11 may have substantially the same structure, and include substantially the same material, as the first passivation layer PET1 of FIG. 8, and thus, a detailed description thereof will be omitted.

The reflective coating layer RCL may be disposed on a surface of the first layer PET11. For example, the reflective coating layer RCL may be coated on the top surface of the first layer PET11. The reflective coating layer RCL may include a reflective material. The reflective coating layer RCL may include a reflective film or a reflective sheet. For example, the reflective coating layer RCL may include a metal-based material such as Ag, Cu, Al, Ni, La, or a combination thereof or ITO, IZO, or ITZO, but the disclosure is not limited thereto.

In the embodiment of FIG. 14, the first passivation layer PET1_2 may include the first layer PET11 and the reflective coating layer RCL, which is coated on the top surface of the first layer PET11, and thus, a second functional layer may not be provided. As the first passivation layer PET1_2 includes the reflective coating layer RCL, light incident upon the top surface of the reflective coating layer RCL from arrays of light-emitting elements ED may be reflected by the top surface of the reflective coating layer RCL and may thus travel in the display direction of a display device 10. Thus, light leaked in the downward direction of the display device 10 through a gap region between first and second electrodes 210 and 220 can be reflected into the display direction of the display device 10, and as a result, the emission efficiency of the display device 10 can be improved.

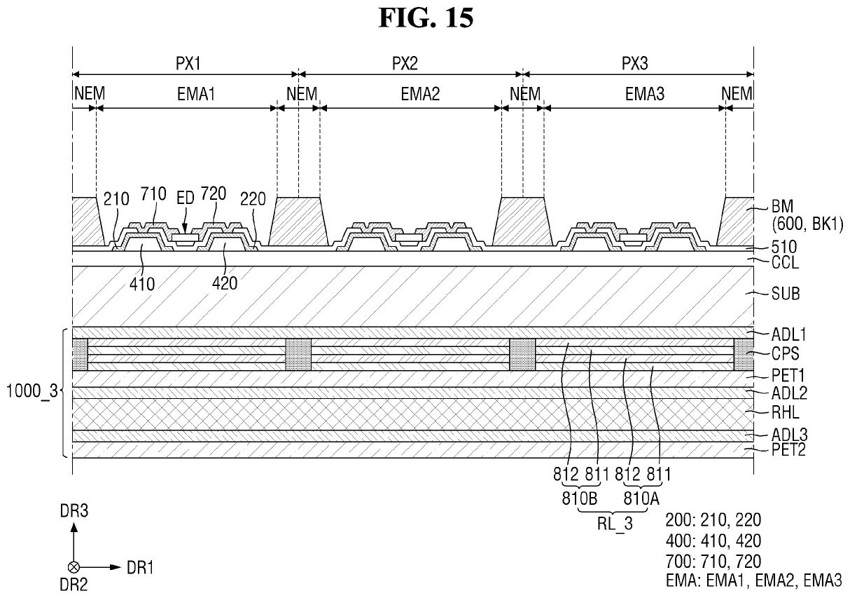

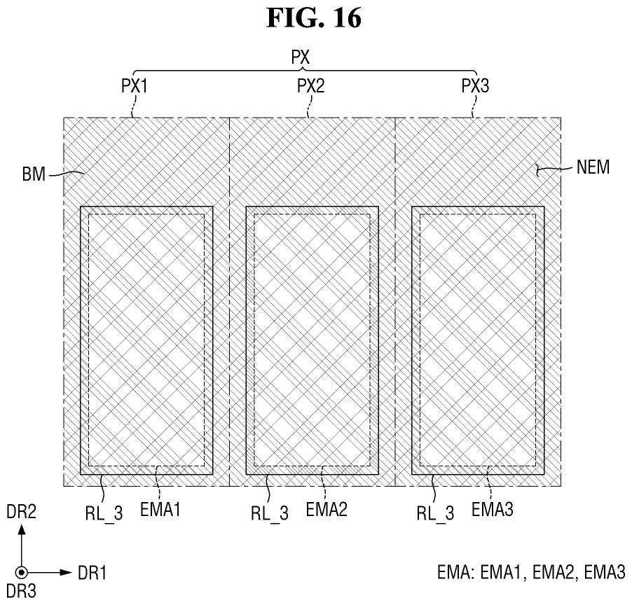

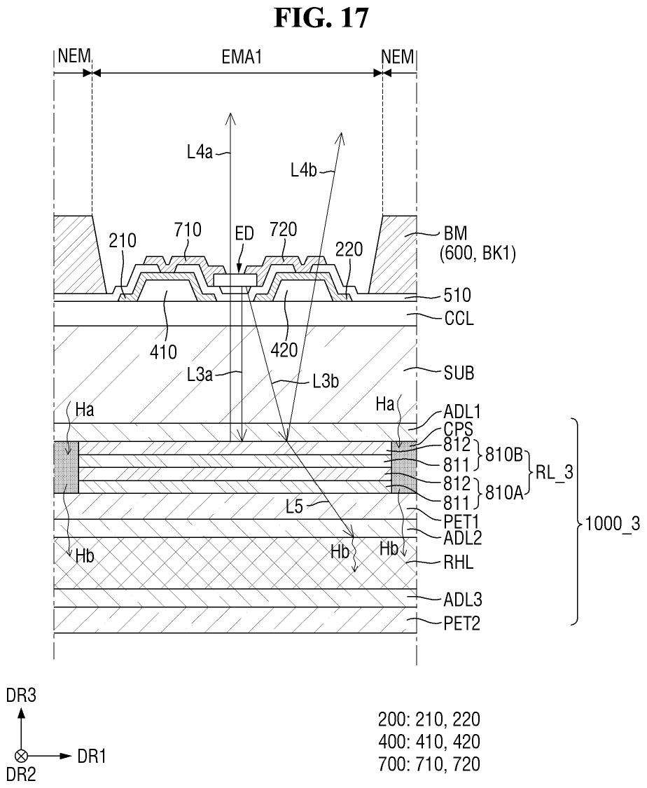

FIG. 15 is a schematic cross-sectional view of a display device according to an embodiment of the disclosure. FIG. 16 is a schematic layout view illustrating the arrangement of a light-blocking member and a second functional layer of the display device of FIG. 15 relative to each other. FIG. 17 is a cross-sectional view illustrating how light emitted from light-emitting elements of the display device of FIG. 15 travels in a downward direction.

The embodiment of FIGS. 15 through 17 differs from the embodiment of FIGS. 8 through 10 in that a functional layer 1000_3 includes reflective patterns RL_3, which are spaced apart from each other.

Referring to FIGS. 15 through 17, the functional layer 1000_3 may include a first functional layer RHL and the reflective patterns RL_3, which are disposed on the first functional layer RHL to be spaced apart from each other.

The reflective patterns RL_3 may be disposed between a first passivation layer PET1 and a first adhesive member ADL1 to be spaced apart from each other. The reflective patterns RL_3 may be disposed to correspond to first, second, and third emission areas EMA1, EMA2, and EMA3. The reflective patterns RL_3 may overlap the first, second, and third emission areas EMA1, EMA2, and EMA3 in a third direction DR3.

The reflective patterns RL_3 may extend outwardly from the first, second, and third emission areas EMA1, EMA2, and EMA3 to overlap parts of light-blocking areas NEM, which surround the first, second, and third emission areas EMA1, EMA2, and EMA3, in the third direction DR3. Thus, the reflective patterns RL_3 may have a greater size than, or the same size as, or the first, second, and third emission areas EMA1, EMA2, and EMA3. As the reflective patterns RL_3 correspond to the first, second, and third emission areas EMA1, EMA2, and EMA3, multiple arrays of light-emitting elements ED, which are disposed in the first, second, and third emission areas EMA1, EMA2, and EMA3, may be covered in the downward direction by the reflective patterns RL_3.

Each of the reflective patterns RL_3 may include at least one optical layer in which multiple inorganic films having different refractive indexes are stacked. The reflective patterns RL_3 may be DBR layers. The reflective patterns RL_3 may have a structure in which optical layers, each including multiple inorganic films having different refractive indexes, are stacked. The reflective patterns RL_3 may be patterns that are formed to have substantially the same structure as the second functional layer RL of FIG. 8 and to correspond to correspond to the first, second, and third emission areas EMA1, EMA2, and EMA3 in a plan view.

The functional layer 1000_3 may further include an adhesive layer CPS, which surrounds the reflective patterns RL_3, between the first passivation layer PET1 and the first adhesive member ADL1. The adhesive layer CPS may be disposed in the light-blocking areas NEM. The adhesive layer CPS may be disposed in the light-blocking areas NEM to surround the reflective patterns RL_3. In a plan view, the reflective patterns RL_3 may not overlap the adhesive layer CPS.

The adhesive layer CPS may include a conductive adhesive material. The adhesive layer CPS may be a conductive adhesive member. The adhesive layer CPS may be formed by mixing an adhesive member and conductive powder. For example, the adhesive layer CPS may be a conductive pressure sensitive adhesive (PSA). In an example, the adhesive layer CPS may be formed by mixing conductive powder (e.g., metal powder) into a PSA.

The adhesive layer CPS may surround the reflective patterns RL_3 in the same layer as the reflective patterns RL_3 between the first passivation layer PET1 and the first adhesive member ADL1. The adhesive layer CPS may fix the reflective patterns RL_3 and may bond the first passivation layer PET1 to the first adhesive member ADL1.

As the adhesive layer CPS includes a conductive material, the adhesive layer CPS may have a higher thermal conductivity than the reflective patterns RL_3. In an embodiment where the reflective patterns RL_3 have a structure in which multiple inorganic films (or multiple insulating films) are stacked, heat generated by a display panel 2000 can be easily delivered to the first functional layer RHL (or a heat dissipation layer).

The reflective patterns RL_3 may completely cover the arrays of light-emitting elements ED in the first, second, and third emission areas EMA1, EMA2, and EMA3, from below, in a cross-sectional view. The reflective patterns RL_3 may overlap parts of the arrays of light-emitting elements ED that are exposed in the downward direction by first electrodes 210 and second electrodes 220.

The reflective patterns RL_3 may overlap parts of a light-blocking member BM along the edges of each of the first, second, and third emission areas EMA1, EMA2, and EMA3, but the disclosure is not limited thereto. In other examples, the reflective patterns RL_3 may not overlap the light-blocking member BM in the third direction DR3.

The adhesive layer CPS may overlap light-blocking areas NEM in the third direction DR3. The adhesive layer CPS may be disposed along the edges of each of the reflective patterns RL_3, and may surround the reflective patterns RL_3. The adhesive layer CPS may overlap the light-blocking member BM in the third direction DR3.

Referring to FIG. 17, some of light emitted from the arrays of light-emitting elements ED may travel in a downward direction into gap regions between the first electrodes 210 and the second electrodes 220. The incidence angle of light traveling in the downward direction through the gap regions between the first electrodes 210 and the second electrodes 220 may be relatively small with respect to the top surface of a substrate SUB. Thus, the reflective patterns RL_3 may concentrate light traveling in the downward direction from the arrays of light-emitting elements ED upon the first, second, and third emission areas EMA1, EMA2, and EMA3, and as a result, the amount of light incident upon the light-blocking areas NEM may be considerably smaller than the amount of light incident upon the first, second, and third emission areas EMA1, EMA2, and EMA3.

In the embodiment of FIGS. 15 through 17, as the reflective patterns RL_3 correspond only to the first, second, and third emission areas EMA1, EMA2, and EMA3, upon which most of the light traveling in the downward direction from the arrays of light-emitting elements ED is incident, the size of the reflective patterns RL_3 can be reduced.

Each of the reflective patterns RL_3 may include multiple inorganic films, and the multiple inorganic films may include an insulating material. The reflective patterns RL_3 may have a low thermal conductivity. In the embodiment of FIGS. 15 through 17, the reflective patterns RL_3 may be selectively formed in regions where light emitted from light-emitting elements ED is incident and light leaked in the downward direction needs to be reflected. The adhesive layer CPS, which includes a conductive material with a high thermal conductivity, may be disposed in other regions. Thus, the manufacturing cost of a display device 10 can be reduced, and the heat dissipation efficiency of the display device 10 can be improved.

Some of the light emitted from the arrays of light-emitting elements ED traveling in the downward direction, i.e., light (L3a and L3b), may be reflected due to the difference in the refractive indices between the multiple inorganic films included in each of the reflective patterns RL_3. The reflected light may travel in the display direction of the display device 10 as light L4a and L4b. Some of the light (L3a and L3b) may continue to travel in the downward direction through the reflective patterns RL_3 as light L5.

Heat Ha generated by the display panel 2000 may be conducted by the adhesive layer CPS, and heat conducted by the adhesive layer CPS may be dissipated to the first functional layer RHL (or a heat dissipation layer) and then released.

According to the embodiment of FIGS. 15 through 17, the heat dissipation efficiency of the display device 10 may be improved due to the adhesive layer CPS having high thermal conductivity.

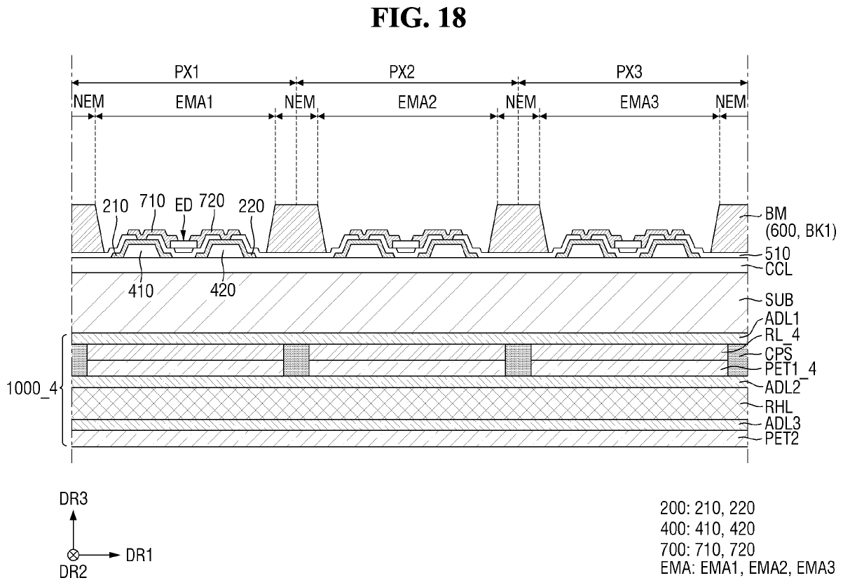

FIG. 18 is a schematic cross-sectional view of a display device according to an embodiment of the disclosure.

The embodiment of FIG. 18 differs from the embodiment of FIG. 15 in that a first passivation layer PET1_4 and reflective patterns RL_4 of a functional layer 1000_4 have a same shape. Also, an adhesive layer CPS surrounds the reflective patterns RL_4 and the first passivation layer PET1_4.

Referring to FIG. 18, the first passivation layer PET1_4 may correspond to first, second, and third emission areas EMA1, EMA2, and EMA3 and may be formed as multiple patterns that are spaced apart from one another. The patterns of the first passivation layer PET1_4 may be formed into the same shape as the reflective patterns RL_4, which are disposed on the first passivation layer PET1_4.

The reflective patterns RL_4 may include a reflective film and/or a reflective sheet. The reflective patterns RL_4 may include a metal-based material such as Ag, Cu, Al, Ni, La, or a combination thereof or ITO, IZO, or ITZO, but the disclosure is not limited thereto.

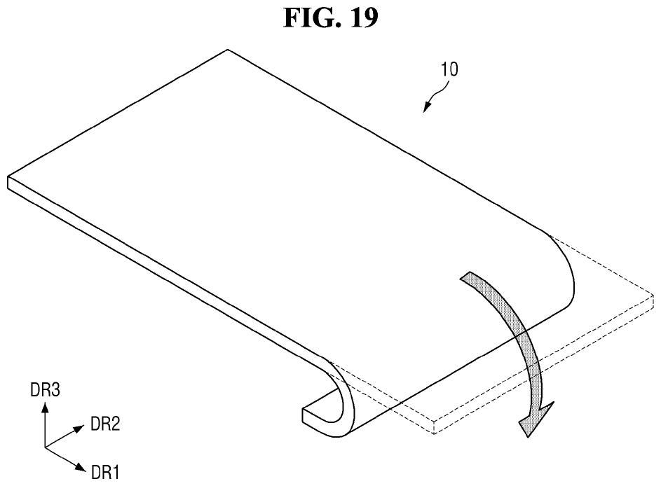

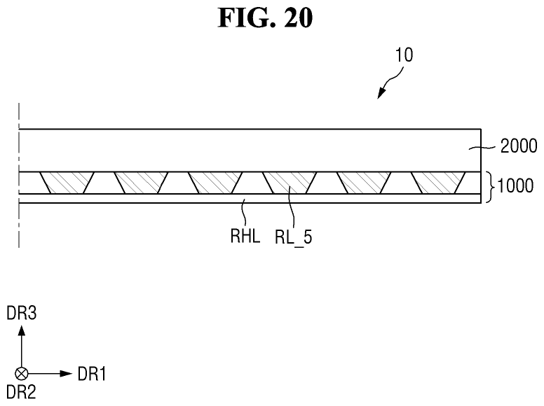

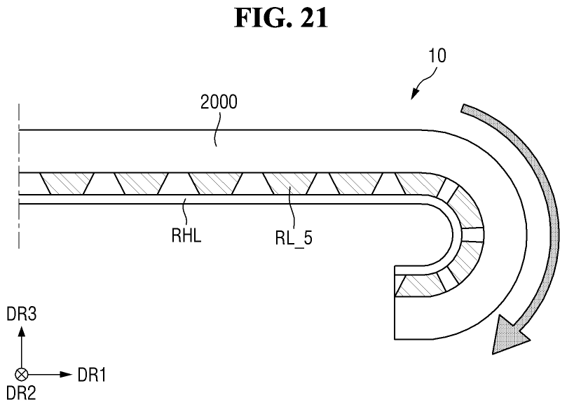

FIG. 19 is a schematic perspective view of a display device in a state of being rolled. FIG. 20 is a schematic cross-sectional view of the display device of FIG. 19. FIG. 21 is a schematic cross-sectional view of the display device of FIG. 20 in a state of being rolled in a downward direction.

Referring to FIGS. 19 and 20, at least part of a display device 10 may be bent or rolled in a downward direction, but the disclosure is not limited thereto. In other examples, the display device 10 may be bent in both an upward direction and a downward direction or may be bent in one of the upward and downward directions. FIG. 19 illustrates the display device 10 being rolled in a first direction DR1, but the disclosure is not limited thereto.

The display device 10 may include a display panel 2000, a first functional layer RHL, which is disposed below the display panel 2000, and reflective patterns RL_5, which are disposed between the display panel 2000 and the first functional layer RHL.

The reflective patterns RL_5 may be spaced apart from each other. The reflective patterns RL_5 may have a rectangular shape in a cross-sectional view, but the disclosure is not limited thereto. In other examples, the reflective patterns RL_5 may have various other shapes such as a square, semielliptical, semicircular, sawtooth, or trapezoidal shape in a cross-sectional view. For example, the reflective patterns RL_5 may have a trapezoidal shape that is wider at the top than at the bottom, in a cross-sectional view, but the disclosure is not limited thereto. As illustrated in FIGS. 20 and 21, as the reflective patterns RL_5 spaced apart from each other, the display device 10 can be easily bent or rolled.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a first electrode and a second electrode disposed on a first surface of a substrate, the first electrode and the second electrode spaced apart from each other;
at least one light-emitting element disposed between the first electrode and the second electrode;
a functional layer disposed on a second surface of the substrate; and
a reflective layer disposed between the functional layer and the second surface of the substrate, the reflective layer overlapping the at least one light-emitting element in a plan view.

2. The display device of claim 1, wherein
the reflective layer includes at least one optical layer,
each of the at least one optical layer includes:
a first inorganic film having a first refractive index; and
a second inorganic film disposed on the first inorganic film and having a second refractive index, and
a value of the second refractive index is different from a value of the first refractive index.

3. The display device of claim 2, wherein
the first inorganic film includes silicon nitride (SiNₓ), and
the second inorganic film includes silicon oxide (SiOₓ).

4. The display device of claim 1, wherein the reflective layer includes at least one of a reflective sheet and a reflective film, the at least one of the reflective sheet and the reflective film including a reflective material.

5. The display device of claim 1, further comprising:
a first insulating layer disposed on the first electrode and the second electrode,
wherein the first electrode and the second electrode do not overlap each other in a plan view.

6. The display device of claim 5, wherein
the at least one light-emitting element is disposed on the first insulating layer, and
at least part of the at least one light-emitting element overlaps a region where the first electrode and the second electrode are spaced apart from each other and face each other in a plan view.

7. The display device of claim 1, wherein the reflective layer overlaps a region where the first electrode and the second electrode are spaced apart from each other and face each other in a plan view.

8. The display device of claim 1 further comprising:
a light-blocking member;
an emission area; and
a light-blocking area surrounding the emission area, wherein
the light-blocking member is disposed in the light-blocking area and surrounds the emission area, and
the at least one light-emitting element is disposed in the emission area.

9. The display device of claim 8, wherein
the reflective layer overlaps the emission area in a plan view, and
a size of the reflective layer is greater than or equal to a size of the emission area.

10. The display device of claim 9, wherein the reflective layer overlaps the light-blocking member in a plan view.

11. A display device comprising:
an emission area and a light-blocking area surrounding the emission area;
a first electrode and a second electrode disposed on a first surface of a substrate in the emission area, the first electrode and the second electrode extending in a first direction and being spaced apart from each other in a second direction which intersects the first direction;
light-emitting elements disposed on the first surface of the substrate, between the first electrode and the second electrode in the emission area;
a light-blocking member disposed on the first surface of the substrate in the light-blocking area, the light-blocking member surrounding the emission area;
a heat dissipation layer disposed on a second surface of the substrate; and
a functional layer disposed between the heat dissipation layer and the substrate, the functional layer overlapping the emission area in a plan view.

12. The display device of claim 11, wherein the functional layer includes a reflective layer.

13. The display device of claim 12, wherein
the functional layer includes at least one optical layer,
each of the at least one optical layer includes:
a first inorganic film having a first refractive index; and
a second inorganic film disposed on the first inorganic film and having a second refractive index, and
a value of the second refractive index is different from a value of the first refractive index.

14. The display device of claim 12, wherein the functional layer does not overlap at least part of the light-blocking member in a plan view.

15. The display device of claim 14, further comprising:
an adhesive layer surrounding the functional layer, wherein the adhesive layer overlaps the light-blocking member in a plan view.

16. The display device of claim 11, wherein
end portions of each of the light-emitting elements are disposed on the first electrode and the second electrode, and
at least part of each of the light-emitting elements overlaps a region where the first electrode and the second electrode are spaced apart from each other and face each other in a plan view.

17. The display device of claim 11, wherein
the functional layer includes:
a passivation layer; and
a reflective coating layer disposed on a surface of the passivation layer, and the surface of the passivation layer faces the second surface of the substrate.

18. A display device comprising:
emission areas and light-blocking areas surrounding the emission areas;
arrays of light-emitting elements disposed on a first surface of a substrate, in the emission areas; and
reflective patterns disposed on a second surface of the substrate, wherein the reflective patterns are disposed to be spaced apart from each other.

19. The display device of claim 18, wherein the reflective patterns are disposed in the emission areas.

20. The display device of claim 18, further comprising:
a light-blocking member disposed on the first surface of the substrate, in the light-blocking areas, wherein
the light-blocking member surrounds the emission areas, and
the reflective patterns do not overlap at least part of the light-blocking member in a plan view.
